(19) United States
(12) Patent Application Publication
(10) Pub. No.: US 2026/0013328 A1
(43) Pub. Date: Jan. 8, 2026

(54) DISPLAY DEVICE AND ELECTRONIC DEVICE INCLUDING THE SAME

(71) Applicant: Samsung Display Co., LTD., Yongin-si (KR)

(72) Inventors: Seung Jun LEE, Yongin-si (KR); Tae Ho KIM, Yongin-si (KR); Gun Hee KIM, Yongin-si (KR); Jae Woo LEE, Yongin-si (KR); Joo Hee JEON, Yongin-si (KR); Sun Young JUNG, Yongin-si (KR)

(21) Appl. No.: 19/061,101

(22) Filed: Feb. 24, 2025

(30) Foreign Application Priority Data
Jul. 3, 2024 (KR) 10-2024-0087687

(51) Int. Cl. H10K 59/121; G09G 3/3233; H10K 59/131

(52) U.S. Cl. CPC H10K 59/1213; G09G 3/3233; H10K 59/1216; H10K 59/1315

(57) ABSTRACT

A display device includes a circuit layer including light-emitting pixel drivers; a first sharing line next to a first boundary between a first light-emitting pixel driver and a second light-emitting pixel driver next to each other, and electrically connected to the first light-emitting pixel driver and the second light-emitting pixel driver; a first semiconductor layer on a substrate; and a second semiconductor layer on a first inter-insulating layer. Each of the light-emitting pixel drivers includes a first transistor of which a channel portion, a first electrode, and a second electrode are disposed in the second semiconductor layer. A first semiconductor layer and a second semiconductor layer of the first light-emitting pixel driver are symmetrical with a first semiconductor layer and a second semiconductor layer of the second light-emitting pixel driver with respect to the first boundary.

This application claims priority to Korean Patent Application No. 10-2024-0087687, filed on Jul. 3, 2024, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

As an information society develops, the demand for a display device for displaying an image is increasing in various forms. For example, the display device is being applied to various electronic devices such as smartphones, digital cameras, laptop computers, navigation devices, and smart televisions.

The display device may be a flat panel display device such as a liquid crystal display device, a field emission display device, or a light-emitting display device. Here, the light-emitting display device may include an organic light-emitting display device including an organic light-emitting element, an inorganic light-emitting display device including an inorganic light-emitting element such as an inorganic semiconductor, and a micro or nano light-emitting display device including a micro or nano light-emitting element.

The organic light-emitting display device displays an image using light-emitting elements each including a light-emitting layer made of an organic light-emitting material. As such, as the organic light-emitting display device implements image display using self-light-emitting elements, the organic light-emitting display device may have relatively superior performance in terms of power consumption, response speed, emission efficiency, luminance, and wide viewing angle compared to other display devices.

One surface of the display device may be a display surface including a display area where an image is displayed and a non-display area surrounding the display area. Light-emitting areas that emit light with respective luminance and color may be arranged in the display area.

### SUMMARY

The display device may include light-emitting elements respectively disposed in light-emitting areas, and light-emitting pixel drivers each electrically connected to the light-emitting elements. Each of the light-emitting pixel drivers may supply a driving current to each of the light-emitting elements.

Each of the light-emitting pixel drivers may include a first transistor for generating a driving current, and a second transistor electrically connected between the first transistor and a data line for transmitting a data signal, and may further include transistors for optional electrical connection, initialization, or reset of some nodes.

In addition, when a channel portion of the first transistor includes an oxide semiconductor, a width of the first transistor may be increased beyond a critical value to secure current characteristics of the first transistor, thereby increasing a width of each of the light-emitting pixel drivers.

As a result, there may be limitations in increasing a resolution of the display device.

Features of the disclosure provide a display device that may be advantageous in increasing a resolution by improving the degree of integration of light-emitting pixel drivers.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, there is provided a display device comprises a substrate including a display area in which light-emitting areas are arranged, and a non-display area disposed around the display area; a circuit layer disposed on the substrate; and an element layer disposed on the circuit layer and including light-emitting elements each disposed in the light-emitting areas. The circuit layer includes light-emitting pixel drivers electrically connected to the light-emitting elements and arranged in a first direction and a second direction; a first sharing line extending in the second direction, next (adjacent) to a first boundary between a first light-emitting pixel driver and a second light-emitting pixel driver next (adjacent) to each other in the first direction among the light-emitting pixel drivers, and electrically connected to the first light-emitting pixel driver and the second light-emitting pixel driver; a first semiconductor layer disposed on the substrate; a first gate insulating layer covering the first semiconductor layer; a first gate conductive layer disposed on the first gate insulating layer; a second gate insulating layer covering the first gate conductive layer; a second gate conductive layer disposed on the second gate insulating layer; a first inter-insulating layer covering the second gate conductive layer; and a second semiconductor layer disposed on the first inter-insulating layer. One of the light-emitting pixel drivers includes a first transistor that generates a driving current for one of the light-emitting elements. A channel portion, a first electrode, and a second electrode of the first transistor are disposed in the second semiconductor layer. A first semiconductor layer and a second semiconductor layer of the first light-emitting pixel driver are symmetrical with a first semiconductor layer and a second semiconductor layer of the second light-emitting pixel driver with respect to the first boundary.

In an embodiment, the light-emitting pixel drivers further include a third light-emitting pixel driver next (adjacent) to the second light-emitting pixel driver in the first direction; a fourth light-emitting pixel driver next (adjacent) to the first light-emitting pixel driver in the second direction; a fifth light-emitting pixel driver next (adjacent) to the second light-emitting pixel driver in the second direction; and a sixth light-emitting pixel driver next (adjacent) to the third light-emitting pixel driver in the second direction. The first semiconductor layer and the second semiconductor layer of the second light-emitting pixel driver are symmetrical with a first semiconductor layer and a second semiconductor layer of the third light-emitting pixel driver with respect to a second boundary between the second light-emitting pixel driver and the third light-emitting pixel driver. The first semiconductor layer and the second semiconductor layer of the first light-emitting pixel driver are symmetrical with a first semiconductor layer and a second semiconductor layer of the fourth light-emitting pixel driver with respect to a third boundary between the first light-emitting pixel driver and the fourth light-emitting pixel driver. The first semiconductor layer and the second semiconductor layer of the second light-emitting pixel driver are symmetrical with a first semiconductor layer and a second semiconductor layer of the fifth light-emitting pixel driver with respect to an extension line of the third boundary. The first sharing line is further electrically connected to the fourth light-emitting pixel driver and the fifth light-emitting pixel driver.

In an embodiment, the circuit layer further includes a data line transmitting a data signal to the light-emitting pixel drivers; a reference voltage line transmitting a reference voltage to the light-emitting pixel drivers; an initialization voltage line transmitting an initialization voltage to the light-emitting pixel drivers; a first power line transmitting a first power to the light-emitting pixel drivers; a scan write line transmitting a scan write signal to the light-emitting pixel drivers; a reset control line transmitting a reset control signal to the light-emitting pixel drivers; a bias control line transmitting a bias control signal to the light-emitting pixel drivers; a first emission control line transmitting a first emission control signal to the light-emitting pixel drivers; and a second emission control line transmitting a second emission control signal to the light-emitting pixel drivers.

In an embodiment, the circuit layer further includes a third gate insulating layer covering the second semiconductor layer; a third gate conductive layer disposed on the third gate insulating layer; a second inter-insulating layer covering the third gate conductive layer; a first source drain conductive layer disposed on the second inter-insulating layer; a first planarization layer covering the first source drain conductive layer; a second source drain conductive layer disposed on the first planarization layer; and a second planarization layer covering the second source drain conductive layer. The one of the light-emitting pixel drivers includes a second transistor electrically connected between a gate electrode of the first transistor and one of the data lines; a third transistor electrically connected between the gate electrode of the first transistor and the reference voltage line; a fourth transistor electrically connected between one of the light-emitting elements and the initialization voltage line; a fifth transistor electrically connected between the first electrode of the first transistor and the first power line; a sixth transistor electrically connected between the second electrode of the first transistor and the one of the light-emitting elements; a first capacitor electrically connected between the gate electrode of the first transistor and the second electrode of the first transistor; and a second capacitor electrically connected between the first power line and the second electrode of the first transistor.

In an embodiment, the first power line includes a first power main line disposed on the third gate conductive layer and extending in the first direction; and a first power sub-line disposed on the second source drain conductive layer and extending in the second direction. The first sharing line includes the first power sub-line.

In an embodiment, the circuit layer further includes an electrode extending portion extending from a first electrode of the sixth transistor; a first capacitor electrode disposed on the first gate conductive layer, overlapping a portion of the electrode extending portion, and electrically connected to the gate electrode of the first transistor; a second capacitor electrode disposed on the second gate conductive layer, overlapping the first capacitor electrode, and electrically connected to the second electrode of the first transistor; a third capacitor electrode disposed on the first gate conductive layer, spaced apart from the first capacitor electrode, overlapping another portion of the electrode extending portion and the second capacitor electrode, and electrically connected to the first power line; a first power connection auxiliary electrode disposed on the first source drain conductive layer and electrically connected to the third capacitor electrode and the first power main line; and a second power connection auxiliary electrode disposed on the first source drain conductive layer and electrically connected to a first electrode of the fifth transistor and the first power main line. A third capacitor electrode of the first light-emitting pixel driver and a third capacitor electrode of the second light-emitting pixel driver are connected to each other at the first boundary. A second power connection auxiliary electrode of the first light-emitting pixel driver and a second power connection auxiliary electrode of the second light-emitting pixel driver are connected to each other at the first boundary. The first capacitor is provided as an overlapping area between each of the electrode extending portion and the second capacitor electrode and the first capacitor electrode. The second capacitor is provided as an overlapping area between each of the electrode extending portion and the second capacitor electrode and the third capacitor electrode.

In an embodiment, a first power connection auxiliary electrode of the second light-emitting pixel driver and a first power connection auxiliary electrode of the third light-emitting pixel driver are connected to each other at the second boundary, and are electrically connected to the first electrode of the fifth transistor of the first semiconductor layer.

In an embodiment, the circuit layer further includes at least one second sharing line extending in the first direction, next (adjacent) to the third boundary, and electrically connected to the first light-emitting pixel driver, the second light-emitting pixel driver, the fourth light-emitting pixel driver, and the fifth light-emitting pixel driver.

In an embodiment, the fourth transistor is turned on by the bias control signal of the bias control line. The bias control line is disposed on the third gate conductive layer, extends in the first direction, and overlaps the third boundary. The at least one second sharing line includes the bias control line.

In an embodiment, the initialization voltage line is disposed on the first source drain conductive layer, extends in the first direction, and overlaps the third boundary. The at least one second sharing line includes the initialization voltage line.

In an embodiment, the fifth transistor is turned on by the first emission control signal of the first emission control line. The sixth transistor is turned on by the second emission control signal of the second emission control line. The second emission control line includes an emission control main line disposed on the first gate conductive layer, extending in the first direction, and overlapping the fourth light-emitting pixel driver and the fifth light-emitting pixel driver; an emission control protruding line protruding from the emission control main line and extending in the second direction; and a reset control extension line connected to the emission control protruding line, extending in the first direction, and overlapping the fifth light-emitting pixel driver and the sixth light-emitting pixel driver. The at least one second sharing line includes the second emission control line.

In an embodiment, the light-emitting pixel drivers further include a seventh light-emitting pixel driver next (adjacent) to the fourth light-emitting pixel driver in the second direction; and an eighth light-emitting pixel driver next (adjacent) to the fifth light-emitting pixel driver in the second direction. A first semiconductor layer and a second semiconductor layer of the seventh light-emitting pixel driver are symmetrical with a first semiconductor layer and a second semiconductor layer of the eighth light-emitting pixel driver with respect to an extension line of the first boundary. The first semiconductor layer and the second semiconductor layer of the seventh light-emitting pixel driver are symmetrical with a first semiconductor layer and a second semiconductor layer of the fourth light-emitting pixel driver with respect to a fourth boundary between the fourth light-emitting pixel driver and the seventh light-emitting pixel driver. The first semiconductor layer and the second semiconductor layer of the eighth light-emitting pixel driver are symmetrical with a first semiconductor layer and a second semiconductor layer of the fifth light-emitting pixel driver with respect to an extension line of the fourth boundary. The circuit layer further includes at least one third sharing line extending in the first direction, next (adjacent) to the fourth boundary, and electrically connected to the fourth light-emitting pixel driver, the fifth light-emitting pixel driver, the seventh light-emitting pixel driver, and the eighth light-emitting pixel driver.

In an embodiment, the third transistor is turned on by the reset control signal of the reset control line. The reset control line includes a reset control main line disposed on the third gate conductive layer, extending in the first direction, and overlapping the fourth light-emitting pixel driver and the fifth light-emitting pixel driver; a reset control protruding line protruding from the reset control main line and extending in the second direction; and a reset control extension line connected to the reset control protruding line, extending in the first direction, and overlapping the seventh light-emitting pixel driver and the eighth light-emitting pixel driver. The at least one third sharing line includes the reset control line.

In an embodiment, the reference voltage line includes a reference voltage main line disposed on the second gate conductive layer, extending in the first direction, and overlapping the fourth boundary; and a reference voltage sub-line disposed on the second source drain conductive layer, extending in the second direction, next (adjacent) to the second boundary, and electrically connected to the reference voltage main line. The at least one third sharing line includes the reference voltage main line.

In an embodiment of the disclosure, there is provided a display device comprises a substrate including a display area in which light-emitting areas are arranged, and a non-display area disposed around the display area; a circuit layer disposed on the substrate; and an element layer disposed on the circuit layer and including light-emitting elements each disposed in the light-emitting areas. The circuit layer includes light-emitting pixel drivers electrically connected to the light-emitting elements and arranged in a first direction and a second direction; data lines extending in the second direction and transmitting a data signal to the light-emitting pixel drivers; a first bypass auxiliary line extending in the first direction and electrically connected to a first data line of the data lines next (adjacent) to the non-display area in the first direction; a second bypass auxiliary line extending in the second direction, next (adjacent) to a second data line of the data lines spaced farther from the non-display area than the first data line in the first direction, and electrically connected to the first bypass auxiliary line; and a first sharing line extending in the second direction, next (adjacent) to a boundary between two light-emitting pixel drivers next (adjacent) to each other in the first direction among the light-emitting pixel drivers, and electrically connected to the two light-emitting pixel drivers. The circuit layer includes a first semiconductor layer disposed on the substrate, and a second semiconductor layer disposed on one or more insulating layers covering the first semiconductor layer. The two light-emitting pixel drivers include the first semiconductor layer and the second semiconductor layer which are mutually symmetrical with respect to the boundary between the two light-emitting pixel drivers. Other two light-emitting pixel drivers next (adjacent) to each other in the second direction among the light-emitting pixel drivers include the first semiconductor layer and the second semiconductor layer which are mutually symmetrical with respect to a boundary between the other two light-emitting pixel drivers.

In an embodiment, the circuit layer includes the first semiconductor layer; a first gate insulating layer covering the first semiconductor layer; a first gate conductive layer disposed on the first gate insulating layer; a second gate insulating layer covering the first gate conductive layer; a second gate conductive layer disposed on the second gate insulating layer; a first inter-insulating layer covering the second gate conductive layer; the second semiconductor layer disposed on the first inter-insulating layer; a third gate insulating layer covering the second semiconductor layer; a third gate conductive layer disposed on the third gate insulating layer; a second inter-insulating layer covering the third gate conductive layer; a first source drain conductive layer disposed on the second inter-insulating layer; a first planarization layer covering the first source drain conductive layer; a second source drain conductive layer disposed on the first planarization layer; and a second planarization layer covering the second source-drain conductive layer. Each of the light-emitting pixel drivers includes a first transistor; a second transistor electrically connected between a data line transmitting the data signal and a gate electrode of the first transistor; a third transistor electrically connected between a reference voltage line transmitting a reference voltage and the gate electrode of the first transistor; a fourth transistor electrically connected between an initialization voltage line transmitting an initialization voltage and the light-emitting elements; a fifth transistor electrically connected between a first power line transmitting a first power and a first electrode of the first transistor; a sixth transistor electrically connected between a second electrode of the first transistor and the light-emitting elements; a first capacitor electrically connected between the gate electrode of the first transistor and the second electrode of the first transistor; and a second capacitor electrically connected between the first power line and the second electrode of the first transistor. A channel portion, a first electrode, and a second electrode of each of the first transistor, the second transistor, the third transistor, and the fourth transistor are disposed on the second semiconductor layer. A channel portion, a first electrode, and a second electrode of each of the fifth transistor and the sixth transistor are disposed on the first semiconductor layer. The third transistor is turned on by a reset control signal of a reset control line. The fourth transistor is turned on by a bias control signal of a bias control line. The fifth transistor is turned on by a first emission control signal of a first emission control line. The sixth transistor is turned on by a second emission control signal of a second emission control line.

In an embodiment, the light-emitting pixel drivers include a first light-emitting pixel driver; a second light-emitting pixel driver next (adjacent) to the first light-emitting pixel driver in the first direction; a third light-emitting pixel driver next (adjacent) to the second light-emitting pixel driver in the first direction; a fourth light-emitting pixel driver next (adjacent) to the first light-emitting pixel driver in the second direction; a fifth light-emitting pixel driver next (adjacent) to the second light-emitting pixel driver in the second direction; a sixth light-emitting pixel driver next (adjacent) to the third light-emitting pixel driver in the second direction; a seventh light-emitting pixel driver next (adjacent) to the fourth light-emitting pixel driver in the second direction; and an eighth light-emitting pixel driver next (adjacent) to the fifth light-emitting pixel driver in the second direction. The first power line includes a first power main line disposed on the third gate conductive layer and extending in the first direction; and a first power sub-line disposed on the second source drain conductive layer and extending in the second direction. The first sharing line is next (adjacent) to a boundary between the first light-emitting pixel driver and the second light-emitting pixel driver, and includes the first power sub-line.

In an embodiment, each of the light-emitting pixel drivers further includes an electrode extending portion extending from a first electrode of the sixth transistor; a first capacitor electrode disposed on the first gate conductive layer, overlapping a portion of the electrode extending portion, and electrically connected to the gate electrode of the first transistor; a second capacitor electrode disposed on the second gate conductive layer, overlapping the first capacitor electrode, and electrically connected to the second electrode of the first transistor; and a third capacitor electrode disposed on the first gate conductive layer, spaced apart from the first capacitor electrode, overlapping another portion of the electrode extending portion and the second capacitor electrode, and electrically connected to the first power line. The first capacitor is provided as an overlapping area between each of the electrode extending portion and the second capacitor electrode and the first capacitor electrode. The second capacitor is provided as an overlapping area between each of the electrode extending portion and the second capacitor electrode and the third capacitor electrode.

In an embodiment, the circuit layer further includes at least one second sharing line extending in the first direction, next (adjacent) to a boundary between the second light-emitting pixel driver and the third light-emitting pixel driver, and electrically connected to the second light-emitting pixel driver, the third light-emitting pixel driver, the fifth light-emitting pixel driver, and the sixth light-emitting pixel driver. The second emission control line includes an emission control main line disposed on the first gate conductive layer, extending in the first direction, and overlapping the fourth light-emitting pixel driver and the fifth light-emitting pixel driver; an emission control protruding line protruding from the emission control main line and extending in the second direction; and a reset control extension line connected to the emission control protruding line, extending in the first direction, and overlapping the fifth light-emitting pixel driver and the sixth light-emitting pixel driver. The at least one second sharing line includes at least one of the bias control line, the initialization voltage line, and the second emission control line.

In an embodiment, the circuit layer further includes at least one third sharing line extending in the first direction, next (adjacent) to a boundary between the fourth light-emitting pixel driver and the seventh light-emitting pixel driver, and electrically connected to the fourth light-emitting pixel driver, the fifth light-emitting pixel driver, the seventh light-emitting pixel driver, and the eighth light-emitting pixel driver. The reference voltage line includes a reference voltage main line disposed on the second gate conductive layer and extending in the first direction; and a reference voltage sub-line disposed on the second source drain conductive layer, extending in the second direction, and electrically connected to the reference voltage main line. The reset control line includes a reset control main line extending in the first direction and overlapping the fourth light-emitting pixel driver and the fifth light-emitting pixel driver; a reset control protruding line protruding from the reset control main line and extending in the second direction; and a reset control extension line connected to the reset control protruding line, extending in the first direction, and overlapping the seventh light-emitting pixel driver and the eighth light-emitting pixel driver. The at least one third sharing line includes at least one of the reference voltage main line and the reset control line.

In an embodiment, the display device in embodiments includes the circuit layer and the element layer disposed on the substrate.

In an embodiment, the element layer may include light-emitting elements respectively disposed in the light-emitting areas.

In an embodiment, the circuit layer may include light-emitting pixel drivers electrically connected to the light-emitting elements of the element layer and arranged in a first direction and a second direction, and a first sharing line extending in the second direction, next (adjacent) to a first boundary between a first light-emitting pixel driver and a second light-emitting pixel driver among the light-emitting pixel drivers, which are next (adjacent) to each other in the first direction, and electrically connected to the first light-emitting pixel driver and the second light-emitting pixel driver. The circuit layer may include a first semiconductor layer disposed on the substrate, and a second semiconductor layer disposed on one or more insulating layers covering the first semiconductor layer. Each of the light-emitting pixel drivers may include a first transistor that generates a driving current for each of the light-emitting elements, and a channel portion, a first electrode, and a second electrode of the first transistor may be disposed in the second semiconductor layer.

In an embodiment, a first semiconductor layer and a second semiconductor layer of the first light-emitting pixel driver may be symmetrical with a first semiconductor layer and a second semiconductor layer of the second light-emitting pixel driver with respect to the first boundary.

In this way, each of the first sharing lines disposed in the display area may be electrically connected to two pixel columns next (adjacent) to each other in the first direction among pixel columns each composed of the light-emitting pixel drivers arranged in parallel in the second direction in the display area. Therefore, the total number of first sharing lines arranged in the display area may be reduced to half the number of pixel columns arranged in the display area.

As a result, since a width of the display area consumed for the arrangement of the first sharing lines may be reduced, it may be advantageous in increasing the resolution of the display device.

In an embodiment, the first sharing line may include a first power sub-line that transmits a first power and is disposed on a second source drain conductive layer.

In embodiments, the light-emitting pixel drivers may include a third light-emitting pixel driver parallel to the second light-emitting pixel driver in the first direction, fourth, fifth, and sixth light-emitting pixel drivers respectively next (adjacent) to the first, second, and third light-emitting pixel drivers in the second direction, and seventh and eighth light-emitting pixel drivers respectively next (adjacent) to the fourth and fifth light-emitting pixel drivers in the second direction.

In embodiments, the circuit layer may further include at least one second sharing line extending in the first direction, next (adjacent) to a third boundary between the first light-emitting pixel driver and the fourth light-emitting pixel driver, and electrically connected to the first, second, fourth, and fifth light-emitting pixel drivers.

The at least one second sharing line may include at least one of a bias control line disposed on a third gate conductive layer and transmitting a bias control signal, an initialization voltage line disposed on a first source drain conductive layer and transmitting an initialization voltage, and a light-emitting control main line disposed on a first gate conductive layer and transmitting a second light-emitting control signal.

In this way, any one of the second sharing lines disposed in the display area may be electrically connected to two pixel rows next (adjacent) to each other in the second direction among pixel rows each composed of the light-emitting pixel drivers arranged in parallel in the first direction in the display area. Therefore, the number of second sharing lines disposed in the display area may be reduced to half the number of pixel rows disposed in the display area.

As a result, since a width of the display area consumed for the arrangement of the second sharing lines may be reduced, it may be advantageous in increasing the resolution of the display device.

In embodiments, the circuit layer may further include at least one third sharing line extending in the first direction, next (adjacent) to a fourth boundary between the fourth light-emitting pixel driver and the seventh light-emitting pixel driver, and electrically connected to the fourth, fifth, seventh, and eighth light-emitting pixel drivers.

In an embodiment, the at least one third sharing line may include at least one of a reference voltage main line transmitting a reference voltage and a second reset control line transmitting a second reset control signal.

In this way, any one of the third sharing lines disposed in the display area may be electrically connected to two pixel rows next (adjacent) to each other in the second direction among the pixel rows. Therefore, the number of third sharing lines disposed in the display area may be reduced to half the number of pixel rows disposed in the display area.

As a result, since a width of the display area consumed for the arrangement of the third sharing lines may be reduced, it may be advantageous in increasing the resolution of the display device.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view illustrating an embodiment of a display device;

FIG. 2 is a plan view illustrating the display device of FIG. 1;

FIG. 3 is a cross-sectional view taken along line A-A′ of FIG. 2;

FIG. 4 is a plan view illustrating portion B of FIG. 2;

FIG. 5 is an equivalent circuit diagram illustrating an embodiment of a light-emitting pixel driver of FIG. 4;

FIG. 6 is a cross-sectional view illustrating a first transistor, a second transistor, a sixth transistor, a first capacitor, a second capacitor, and a light-emitting element of FIG. 5;

FIG. 7 is a plan view illustrating an embodiment of a substrate of FIG. 3;

FIG. 8 is a plan view illustrating a circuit layer of portion D of FIG. 7;

FIG. 9 is a plan view illustrating a circuit layer of portion E of FIG. 7;

FIG. 10 is a plan view illustrating an embodiment of portion F of FIG. 8;

FIG. 11 is a plan view illustrating an embodiment of portion G of FIG. 8;

FIG. 12 is a plan view illustrating an embodiment of a first semiconductor layer and a second semiconductor layer of portion C of FIG. 4;

FIG. 13 is a plan view illustrating a first semiconductor layer, a first gate conductive layer, and a second gate conductive layer of portion H of FIG. 12;

FIG. 14 is a plan view illustrating a second semiconductor layer and a third gate conductive layer of portion H of FIG. 12;

FIG. 15 is a plan view illustrating a first source drain conductive layer of portion H of FIG. 12;

FIG. 16 is a plan view illustrating a second source drain conductive layer of portion H of FIG. 12;

FIG. 17 is a plan view illustrating an embodiment of a second gate conductive layer, a second semiconductor layer, and a third gate conductive layer of portion I of FIG. 12; and

FIG. 18 is a plan view illustrating a first semiconductor layer, a first gate conductive layer, and a second gate conductive layer of portion J of FIG. 12;

FIG. 19 is a block diagram illustrating an embodiment of an electronic device; and

FIG. 20 is a view illustrating an embodiment of the electronic device of FIG. 19 implemented as a smartphone.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying drawing figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it may be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

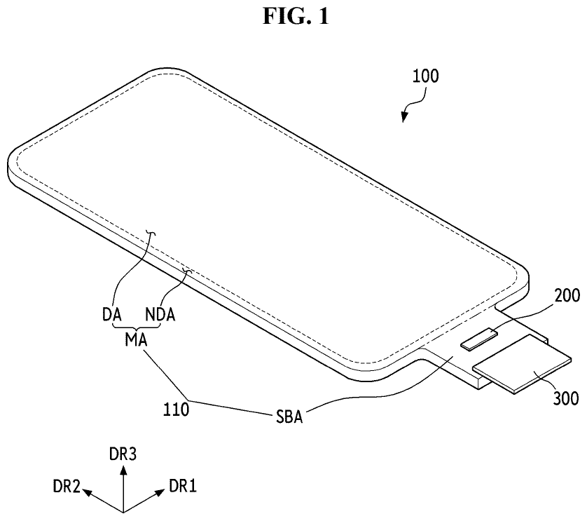

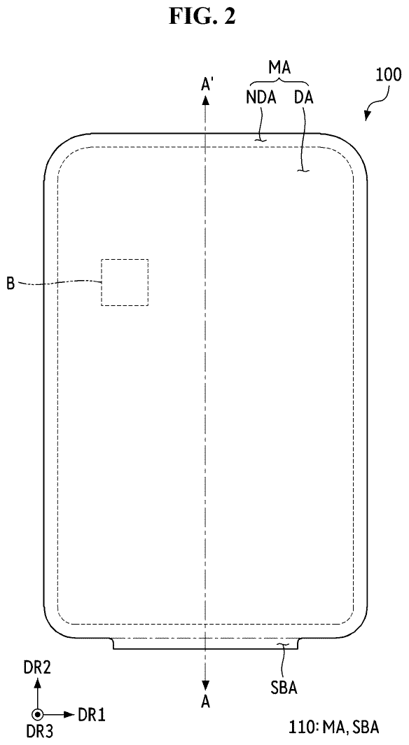

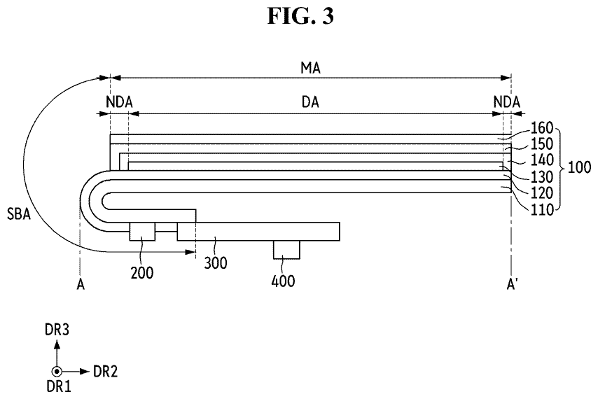

FIG. 1 is a perspective view illustrating an embodiment of a display device. FIG. 2 is a plan view illustrating the display device of FIG. 1. FIG. 3 is a cross-sectional view taken along line A-A′ of FIG. 2.

Referring to FIGS. 1 and 2, a display device 100 is a device that displays a moving image or a still image, and may be used as a display screen of each of various products such as a television, a laptop computer, a monitor, a billboard, and an Internet of Things (“IoT”) device as well as portable electronic devices such as a mobile phone, a smartphone, a tablet personal computer (“PC”), a smartwatch, a watch phone, a mobile communication terminal, an electronic organizer, an electronic book, a portable multimedia player (“PMP”), a navigation device, and an ultra mobile PC (“UMPC”).

The display device 100 may be a light-emitting display device such as an organic light-emitting display device using an organic light-emitting diode, a quantum dot light-emitting display device including a quantum dot light-emitting layer, an inorganic light-emitting display device including an inorganic semiconductor, and a micro light-emitting display device using a micro or nano light-emitting diode (micro or nano light-emitting diode (“LED”)). Hereinafter, the description will be mainly made based on the fact that the display device 100 is an organic light-emitting display device. However, the disclosure is not limited thereto and may be applied to display devices including organic insulating materials, organic light-emitting materials, and metal materials.

The display device 100 may be flat, but is not limited thereto. In an embodiment, the display device 100 may include curved surface portions formed at left and right distal ends thereof and having a constant curvature or a variable curvature, for example. In addition, the display device 100 may be flexibly formed to be curved, bent, folded, or rolled.

As illustrated in FIGS. 1, 2, and 3, the display device 100 includes a substrate 110.

The substrate 110 may include a main area MA corresponding to a display surface of the display device 100 and a sub-area SBA protruding from one side of the main area MA.

As illustrated in FIG. 2, the main area MA may include a display area DA disposed at most of the center and a non-display area NDA disposed around the display area DA.

The display area DA may be formed in a quadrangular plane, e.g., rectangular plane having a short side in a first direction DR1 and a long side in a second direction DR2 intersecting the first direction DR1. A corner where the short side in the first direction DR1 and the long side in the second direction DR2 meet may be rounded to have a predetermined curvature or may be formed at a right angle. The planar shape of the display area DA is not limited to the quadrangular shape, and the display area DA may be formed in other polygonal, circular, or oval shapes.

The non-display area NDA may be disposed at an edge of the main area MA to surround the display area DA.

The sub-area SBA may be an area extending in the second direction DR2 from a portion of one side of the main area MA extending in the first direction DR1.

The sub-area SBA may include a bending area (BA in FIG. 3) that is deformed into a curved shape.

FIGS. 2 and 3 illustrate the display device 100 with a portion of the sub-area SBA curved.

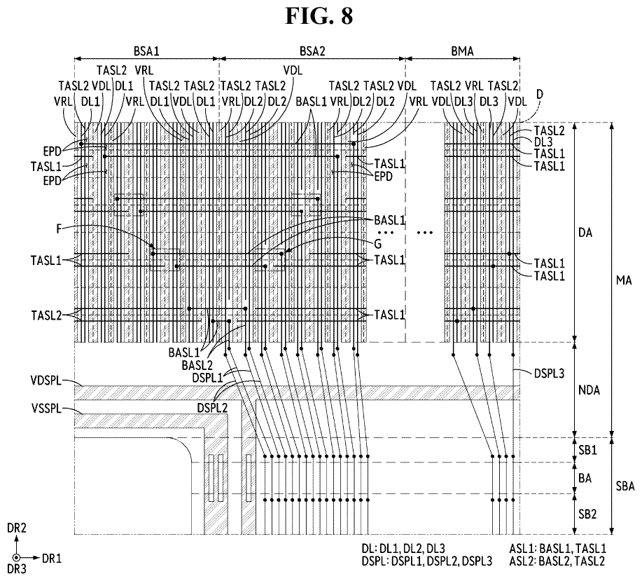

As illustrated in FIG. 3, the sub-area SBA may include a bending area BA (refer to FIG. 8) that is deformed into a bent shape, a first sub-area SB1 (refer to FIG. 8) disposed between one side of the main area MA and one side of the bending area BA, and a second sub-area SB2 (refer to FIG. 8) extending from an opposite side of the bending area BA.

When the bending area BA is deformed into the bent shape, the second sub-area SB2 may be disposed on a rear surface of the display device 100 and may overlap the main area MA.

A display driving circuit 200 provided as an integrated circuit chip (“IC”) may be disposed (e.g., mounted) in the second sub-area SB2.

A circuit board 300 may be bonded to one side of the second sub-area SB2.

A touch driving circuit 400 provided as an integrated circuit chip (“IC”) may be disposed (e.g., mounted) on the circuit board 300.

Referring to FIG. 3, the display device 100 in the embodiments includes a substrate 110, a circuit layer 120 disposed on the substrate 110, and an element layer 130 disposed on the circuit layer 120.

The display device 100 in the embodiments may further include a sealing layer 140 disposed on the element layer 130, and a touch sensor layer 150 disposed on the sealing layer 140.

In addition, the display device 100 in the embodiments may further include a polarizing layer 160 disposed on the touch sensor layer 150 to reduce reflection of external light.

The substrate 110 may include or consist of an insulating material such as a polymer resin. In an embodiment, the substrate 110 may include or consist of polyimide, for example.

The substrate 110 may be a flexible substrate that may be bent, folded, and rolled.

In an alternative embodiment, the substrate 110 may include or consist of an insulating material such as glass.

The substrate 110 may include a main area MA and a sub-area SBA. The main area MA may include a display area DA and a non-display area NDA.

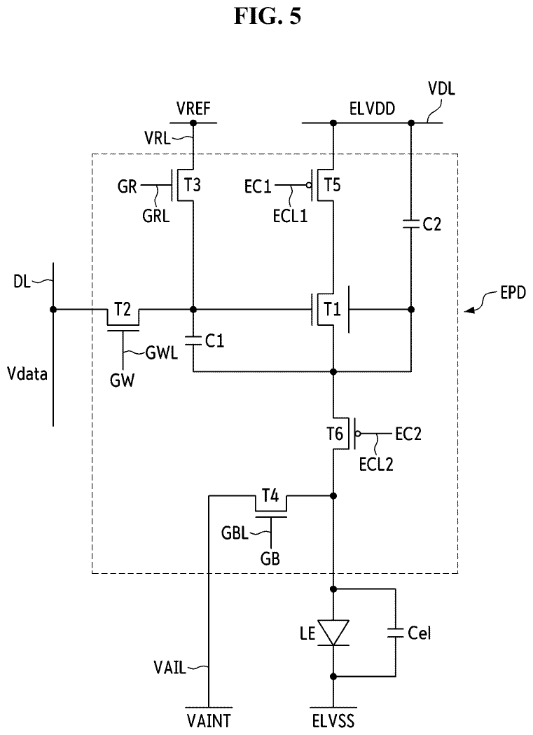

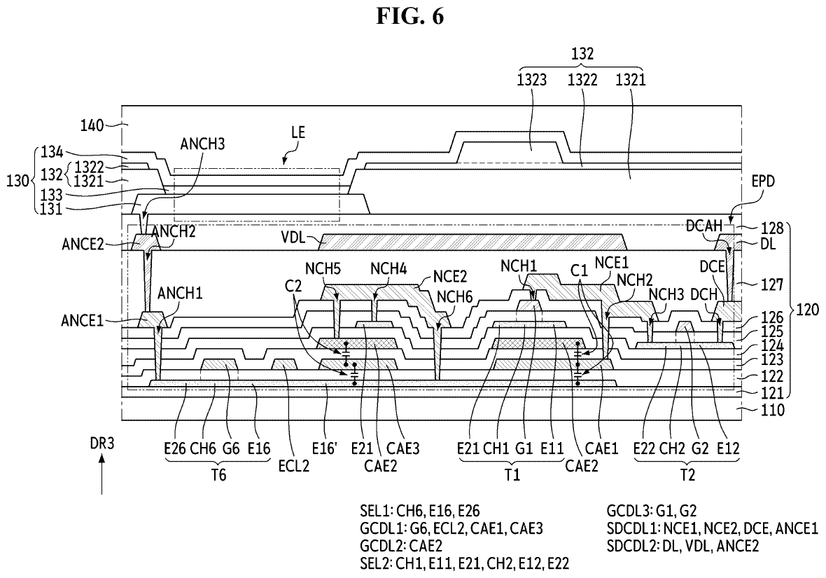

The element layer 130 may include light-emitting elements (LE in FIGS. 5 and 6) respectively disposed in the light-emitting areas EA.

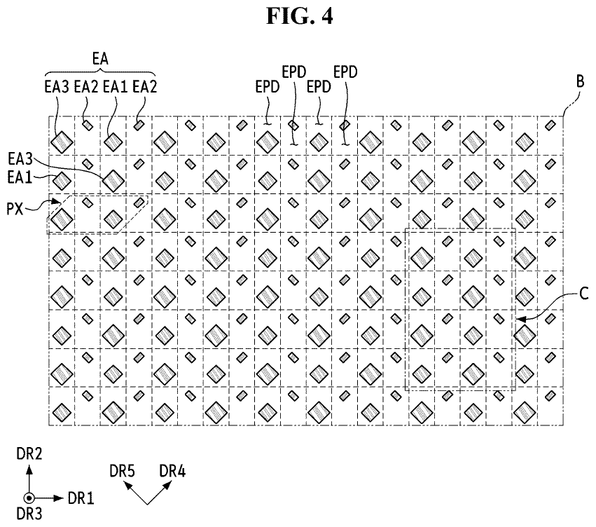

The circuit layer 120 may include light-emitting pixel drivers (EPD in FIG. 4) that are electrically connected to the light-emitting elements LE of the element layer 130, respectively.

The sealing layer 140 is disposed on the element layer 130 and may have a structure in which at least one organic film is interposed between two or more inorganic films.

The touch sensor layer 150 may include touch electrodes for detecting a signal that varies depending on a touch of a person or object and sensing a point in the main area MA where the touch of the person or object occurred.

The polarizing layer 160 is to prevent image visibility from being reduced due to reflection of external light by blocking external light reflected from the touch sensor layer 150, the sealing layer 140, the element layer 130, and the circuit layer 120 and interfaces therebetween.

In embodiments, the display device 100 may further include a display driving circuit 200 provided as an integrated circuit chip (“IC”) and disposed (e.g., mounted) in the sub-area SBA of the substrate 110.

The display driving circuit 200 may supply data signals (Vdata in FIG. 5) to data lines (DL in FIGS. 5 and 6) of the circuit layer 120.

In embodiments, the display device 100 may further include a circuit board 300 bonded to the sub-area SBA of the substrate 110. The circuit board 300 may be bonded to pads disposed in the sub-area SBA of the substrate 110 using a low-resistance and high-reliability material such as an anisotropic conductive film or a sintered silver adhesive paste (“SAP”).

The touch driving circuit 400 may be disposed (e.g., mounted) on the circuit board 300.

When the touch sensor layer 150 includes capacitive touch electrodes and sensing electrodes, the touch driving circuit 400 may sense a touch based on whether or not a capacitance changes. However, this is merely one of embodiments, and the touch sensor layer 150 and touch driving circuit 400 of FIG. 3 may be provided in a touch sensing method other than the capacitive method.

FIG. 4 is a plan view illustrating portion B of FIG. 2.

Referring to FIG. 4, the display area DA of the display device 100 in embodiments may include light-emitting areas EA. In addition, the display area DA may further include a non-light-emitting area disposed in a spaced portion between the light-emitting areas EA.

Light-emitting pixel drivers EPD each corresponding to the light-emitting areas EA may be arranged in the display area DA to be parallel to each other in the first direction DR1 and the second direction DR2. The light-emitting pixel drivers EPD may be electrically connected to light-emitting elements (LE in FIGS. 5 and 6) of the element layer 130 each disposed in the light-emitting areas EA.

The light-emitting areas EA may have a rhombic planar shape or a quadrangular, e.g., rectangular planar shape. However, this is only an illustrative embodiment, and the planar shape of the light-emitting areas EA in an embodiment is not limited to that illustrated in FIG. 4. That is, the light-emitting areas EA may have a polygonal planar shape such as a square, pentagon, or hexagon, or a circular or oval planar shape including curved edges.

The light-emitting areas EA may include first light-emitting areas EA1 that emit light in a first wavelength band, second light-emitting areas EA2 that emit light in a second wavelength band lower than the first wavelength band, and third light-emitting areas EA3 that emit light in a third wavelength band lower than the second wavelength band.

In an embodiment, the first wavelength band may correspond to red and may be from about 600 nanometers (nm) to about 750 nm, for example. The second wavelength band may correspond to green and may be from about 480 nm to about 560 nm. The third wavelength band may correspond to blue and may be from about 370 nm to about 460 nm.

The first light-emitting areas EA1 and the third light-emitting areas EA3 may be alternately arranged in the first direction DR1 or the second direction DR2.

The second light-emitting areas EA2 may be arranged to be parallel to each other in the first direction DR1 or the second direction DR2.

In addition, the second light-emitting areas EA2 may be next (adjacent) to the first light-emitting areas EA1 and the third light-emitting areas EA3 in diagonal directions DR4 and DR5 intersecting the first and second directions DR1 and DR2.

Pixels PX that display each luminance and color may be provided by the first light-emitting area EA1, the second light-emitting area EA2, and the third light-emitting area EA3 next (adjacent) to each other among the light-emitting areas EA.

In other words, the pixels PX may be basic units that display various colors, including white, at predetermined luminance.

Each of the pixels PX may include at least one first light-emitting area EA1, at least one second light-emitting area EA2, and at least one third light-emitting area EA3 next (adjacent) to each other. Accordingly, each of the pixels PX may display various colors through mixing of light emitted from the first, second, and third light-emitting areas EA1, EA2, and EA3 next (adjacent) to each other.

FIG. 5 is an equivalent circuit diagram illustrating an embodiment of a light-emitting pixel driver of FIG. 4.

Referring to FIG. 5, the circuit layer (120 in FIG. 3) may include a first power line VDL that transmits a first power ELVDD to the light-emitting pixel drivers EPD, a second power line that transmits a second power ELVSS to the light-emitting elements LE, a reference voltage line VRL that transmits a reference voltage VREF to the light-emitting pixel drivers EPD, and an initialization voltage line VAIL that transmits an initialization voltage VAINT.

The light-emitting elements LE of the element layer (130 in FIG. 3) may be electrically connected between the light-emitting pixel drivers EPD and the second power ELVSS.

That is, one of the light-emitting elements LE may be electrically connected between one of the light-emitting pixel drivers EPD of the circuit layer 120 and the second power ELVSS.

The second power ELVSS may have a lower voltage level than the first power ELVDD.

That is, an anode electrode of the light-emitting element LE may be electrically connected to the light-emitting pixel driver EPD, and the second power ELVSS having the lower voltage level than the first power ELVDD may be applied to a cathode electrode of the light-emitting element LE.

A capacitor Cel connected in parallel with the light-emitting element LE represents a parasitic capacitance between the anode electrode and the cathode electrode.

The circuit layer 120 may include a scan write line GWL transmitting a scan write signal GW, a reset control line GRL transmitting a reset control signal GR, a bias control line GBL transmitting a bias control signal GB, a first emission control line ECL1 transmitting a first emission control signal EC1, and a second emission control line ECL2 transmitting a second emission control signal EC2.

One light-emitting pixel driver EPD of the circuit layer 120 may include a first transistor T1 that generates a driving current for driving the light-emitting element LE, two or more transistors T2 to T6 electrically connected to the first transistor T1, and one or more capacitors C1 and C2.

The second transistor T2 may be electrically connected between a gate electrode of the first transistor T1 and the data line DL.

The second transistor T2 may be turned on by the scan write signal GW of the scan write line GWL.

When the second transistor T2 is turned on, the data signal Vdata of the data line DL may be transmitted to the gate electrode of the first transistor T1.

When a voltage difference between the gate electrode of the first transistor T1 and the second electrode of the first transistor T1 is equal to or greater than a threshold voltage of the first transistor T1 by the data signal Vdata applied to the gate electrode of the first transistor T1, the first transistor T1 may be turned on. Accordingly, a drain-source current of the first transistor T1 may be generated in a size corresponding to the data signal Vdata.

The third transistor T3 may be electrically connected between the gate electrode of the first transistor T1 and the reference voltage line VRL.

The third transistor T3 may be turned on by the reset control signal GR of the reset control line GRL.

When the third transistor T3 is turned on, a potential of the gate electrode of the first transistor T1 may be reset to the reference voltage VREF of the reference voltage line VRL.

The fourth transistor T4 may be electrically connected between the light-emitting element LE and the initialization voltage line VAIL.

The fourth transistor T4 may be turned on by the bias control signal GB of the bias control line GBL.

When the fourth transistor T4 is turned on, the potential of the anode electrode of the light-emitting element LE may be initialized to the initialization voltage VAINT of the initialization voltage line VAIL.

The fifth transistor T5 may be electrically connected between the first electrode of the first transistor T1 and the first power line VDL.

The fifth transistor T5 may be turned on by the first emission control signal EC1 of the first emission control line ECL1.

When the fifth transistor T5 is turned on, the first power ELVDD of the first power line VDL may be transmitted to the first electrode of the first transistor T1.

The sixth transistor T6 may be electrically connected between the second electrode of the first transistor T1 and the light-emitting element LE.

The sixth transistor T6 may be turned on by the second emission control signal EC2 of the second emission control line ECL2.

When the sixth transistor T6 is turned on, the drain-source current of the first transistor T1 generated in the size corresponding to the data signal Vdata may be transmitted to the light-emitting element LE through the sixth transistor T6.

As a result, the light-emitting element LE may emit light with luminance corresponding to the data signal Vdata.

The first capacitor C1 may be electrically connected between the gate electrode of the first transistor T1 and the second electrode of the first transistor T1.

Accordingly, the first capacitor C1 may be charged with the data signal Vdata applied to the gate electrode of the first transistor T1, and due to the voltage charged to the first capacitor C1, the turn-on of the first transistor T1 may be maintained for a predetermined period of time.

The second capacitor C2 may be electrically connected between the second electrode of the first transistor T1 and the first power line VDL.

The voltage of the first capacitor C1 may correspond to a potential difference between the gate electrode of the first transistor T1 and the second electrode of the first transistor, may be varied by the data signal Vdata, and may be divided by the second capacitor C2. Accordingly, the threshold voltage of the first transistor T1 may be compensated.

In embodiments, the first transistor T1 may include a gate electrode and a gate additional electrode that face opposite sides of the channel portion.

The gate electrode of the first transistor T1 may be electrically connected to the second transistor T2.

The gate electrode of the first transistor T1 may be electrically connected to the second electrode of the first transistor T1.

Accordingly, when the first transistor T1 is turned on by applying the data signal Vdata to the gate electrode of the first transistor T1, another portion of the channel portion of the first transistor T1 next (adjacent) to the gate electrode may not be activated compared to a portion of the channel portion of the first transistor T1 next (adjacent) to the gate electrode.

Therefore, since electron mobility in the channel portion of the first transistor T1 is reduced, a slope of a current curve representing a relationship between the voltage of the gate electrode and the source-drain current of the first transistor T1 may become gentle. Accordingly, since a driving voltage range of the first transistor T1 may be widened, the ease of luminance control may be improved.

As illustrated in FIG. 5, the first transistor T1 may be an N-type metal-oxide-semiconductor field-effect transistor (“MOSFET”). In addition, at least some of the second to sixth transistors T2 to T6 may be P-type MOSFETs. In an embodiment, the fifth transistor T5 and the sixth transistor T6 may be P-type MOSFETs, and the second transistor T2, the third transistor T3, and the fourth transistor T4 may be N-type MOSFETs.

Accordingly, in embodiments, the circuit layer 120 may include first semiconductor layers (CH6, E16, and E26 in FIG. 6) for preparing the P-type MOSFET, and second semiconductor layers (CH1, E11, E21, CH2, E12, and E22 in FIG. 6) for preparing the N-type MOSFET.

FIG. 6 is a cross-sectional view illustrating a first transistor, a second transistor, a sixth transistor, a first capacitor, a second capacitor, and a light-emitting element of FIG. 5.

Referring to FIG. 6, the display device 100 in embodiments includes a substrate 110, a circuit layer 120 on the substrate 110, and an element layer 130 on the circuit layer 120.

The display device 100 may further include a sealing layer 140 on the element layer 130.

In embodiments, the circuit layer 120 may include a first semiconductor layer SEL1 disposed on the substrate 110, a first gate insulating layer 122 covering the first semiconductor layer SEL1, a first gate conductive layer GCDL1 disposed on the first gate insulating layer 122, a second gate insulating layer 123 covering the first gate conductive layer GCDL1, a second gate conductive layer GCDL2 disposed on the second gate insulating layer 123, a first inter-insulating layer 124 covering the second gate conductive layer GCDL2, a second semiconductor layer SEL2 disposed on the first inter-insulating layer 124, a third gate insulating layer 125 covering the second semiconductor layer SEL2, a third gate conductive layer GCDL3 disposed on the third gate insulating layer 125, a second inter-insulating layer 126 covering the third gate conductive layer GCDL3, a first source drain conductive layer SDCDL1 disposed on the second inter-insulating layer 126, a first planarization layer 127 covering the first source drain conductive layer SDCDL1, a second source drain conductive layer SDCDL2 disposed on the first planarization layer 127, and a second planarization layer 128 covering the second source drain conductive layer SDCDL2.

In embodiments, the circuit layer 120 may further include a buffer layer 121 covering the substrate 110. In this case, the first semiconductor layer SEL1 may be disposed on the buffer layer 121.

As described above with reference to FIG. 5, the light-emitting pixel driver EPD may include the first transistor T1 and the two or more transistors T2 to T6 electrically connected to the first transistor T1.

The first, second, third and fourth transistors T1, T2, T3, and T4 may be N-type MOSFETs, and the fifth and sixth transistors T5 and T6 may be P-type MOSFETs.

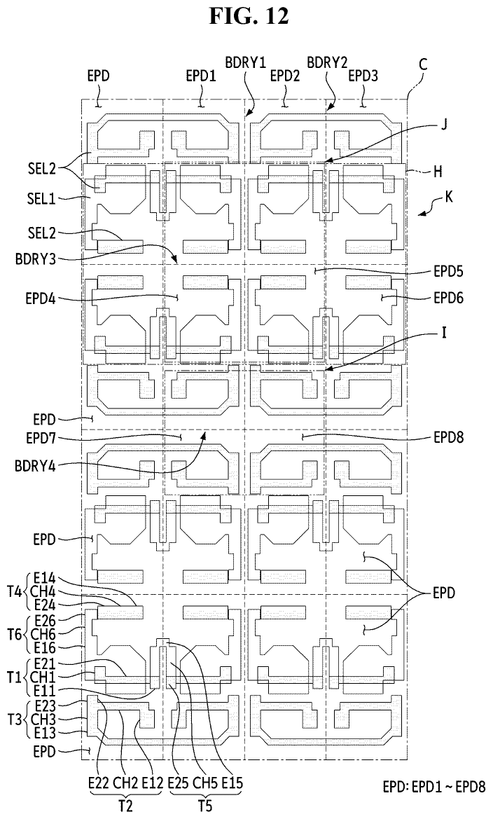

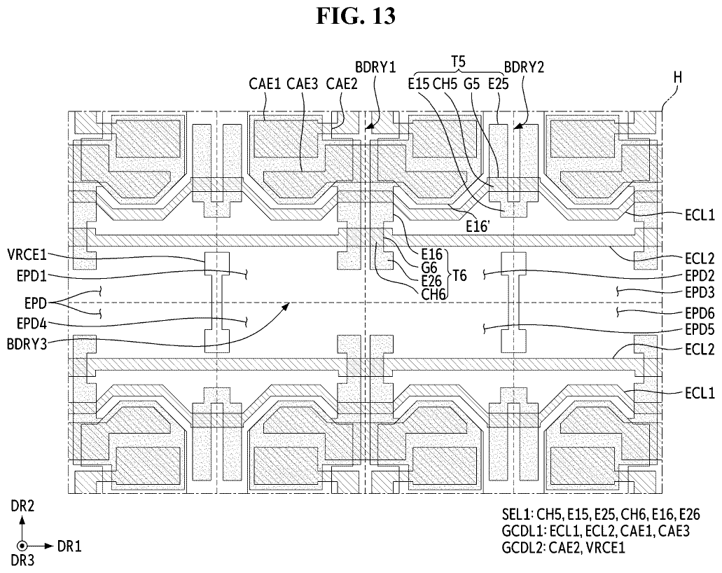

Each of the fifth and sixth transistors T5 and T6 provided as the P-type MOSFETs may include a channel portion (CH5 and CH6 in FIG. 12), a first electrode (E15 and E16 in FIG. 12), and a second electrode (E25 and E26 in FIG. 12) provided on the first semiconductor layer SEL1, and a gate electrode (G5 and G6 in FIG. 13) disposed on the first gate conductive layer GCDL1 and overlapping the channel portions CH5 and CH6.

In an embodiment, the first semiconductor layer SEL1 may include a silicon semiconductor material such as polysilicon or amorphous silicon.

That is, the sixth transistor T6 may include a channel portion CH6 disposed on the first semiconductor layer SEL1, a first electrode E16 and E16′ disposed on the first semiconductor layer SEL1 and connected to one side of the channel portion CH6, a second electrode E26 disposed on the first semiconductor layer SEL1 and connected to an opposite side of the channel portion CH6, and a gate electrode G6 disposed on the first gate conductive layer GCDL1 and overlapping the channel portion CH6.

Since the fifth transistor T5 is the same P-type MOSFET as the sixth transistor T6, the redundant description will be omitted below.

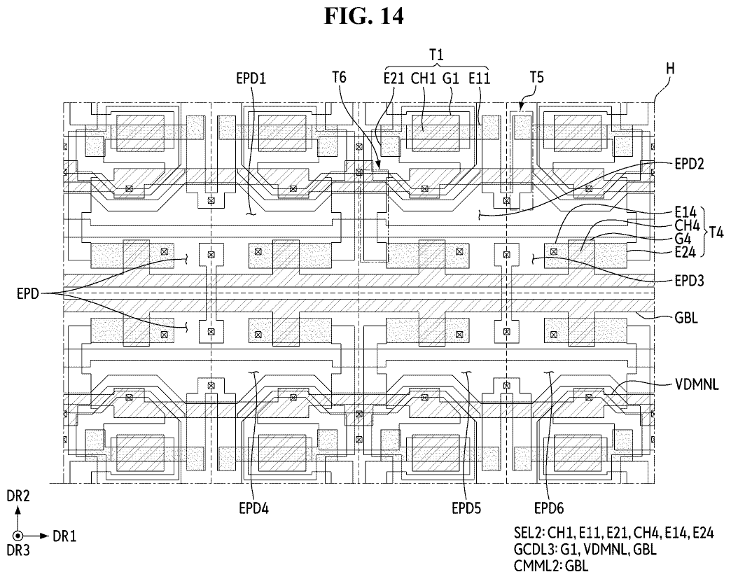

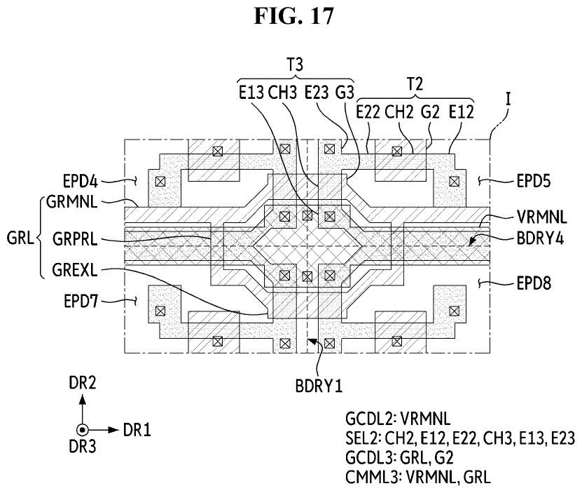

Each of the first, second, third and fourth transistors T1, T2, T3, and T4 provided as the N-type MOSFETs may include a channel portions (CH1, CH2, CH3, and CH4 in FIG. 12), a first electrode (E11, E12, E13, and E14 in FIG. 12), and a second electrode (E21, E22, E23, and E24 in FIG. 12) disposed on the second semiconductor layer SEL2, and a gate electrode (G1 and G4 in FIG. 14, and G2 and G3 in FIG. 17) disposed on the third gate conductive layer GCDL3 and overlapping the channel portions CH1, CH2, CH3, and CH4.

In an embodiment, the second semiconductor layer SEL2 may include an oxide semiconductor material.

That is, the first transistor T1 may include a channel portion CH1 disposed on the second semiconductor layer SEL2, a first electrode E11 disposed on the second semiconductor layer SEL2 and connected to one side of the channel portion CH1, a second electrode E21 disposed on the second semiconductor layer SEL2 and connected to an opposite side of the channel portion CH1, and a gate electrode G1 disposed on the third gate conductive layer GCDL3 and overlapping the channel portion CH1.

An upper surface of the channel portion CH1 of the first transistor T1 may face the gate electrode G1.

In addition, a lower surface of the channel portion CH1 of the first transistor T1 may face a second capacitor electrode CAE2 that is electrically connected to the second electrode E21 of the first transistor T1.

That is, the second capacitor electrode CAE2 may be the gate additional electrode of the first transistor T1.

The second transistor T2 may include a channel portion CH2 disposed on the second semiconductor layer SEL2, a first electrode E12 disposed on the second semiconductor layer SEL2 and connected to one side of the channel portion CH2, a second electrode E22 disposed on the second semiconductor layer SEL2 and connected to an opposite side of the channel portion CH2, and a gate electrode G2 disposed on the third gate conductive layer GCDL3 and overlapping the channel portion CH2.

The first electrode E12 of the second transistor T2 may be electrically connected to the data line DL through a data connection electrode DCE.

The data connection electrode DCE may be disposed on the first source drain conductive layer SDCDL1 on the second inter-insulating layer 126, and may be electrically connected to the first electrode E12 of the second transistor T2 through a data connection hole DCH.

The data connection hole DCH may penetrate through the second inter-insulating layer 126 and the third gate insulating layer 125.

The data line DL may be disposed on the second source drain conductive layer SDCDL2 on the first planarization layer 127, and may be electrically connected to the data connection electrode DCE through a data additional connection hole DCAH penetrating through the first planarization layer 127.

The second electrode E22 of the second transistor T2 may be electrically connected to the gate electrode G1 of the first transistor T1 through a first node connection electrode NCE1.

The first node connection electrode NCE1 may be disposed on the first source drain conductive layer SDCDL1 on the second inter-insulating layer 126.

The first node connection electrode NCE1 may be electrically connected to the gate electrode G1 of the first transistor T1 through a first node connection hole NCH1, may be electrically connected to the first capacitor electrode CAE1 through a second node connection hole NCH2, and may be electrically connected to the second electrode E22 of the second transistor T2 through a third node connection hole NCH3.

The first capacitor electrode CAE1 may be disposed on the first gate conductive layer GCDL1 on the first gate insulating layer 122.

The second electrode E21 of the first transistor T1 may be electrically connected to the first electrode E16 of the sixth transistor T6 through a second node connection electrode NCE2.

The second node connection electrode NCE2 may be disposed on the first source drain conductive layer SDCDL1 on the second inter-insulating layer 126.

The second node connection electrode NCE2 may be electrically connected to the second electrode E21 of the first transistor T1 through a fourth node connection hole NCH4, may be electrically connected to the second capacitor electrode CAE2 through a fifth node connection hole NCH5, and may be electrically connected to the first electrode E16 of the sixth transistor T6 through a sixth node connection hole NCH6.

The second capacitor electrode CAE2 may be disposed on the second gate conductive layer GCDL2 on the second gate insulating layer 123.

Since the first capacitor electrode CAE1 is electrically connected to the gate electrode G1 of the first transistor T1 and the second capacitor electrode CAE2 is electrically connected to the second electrode E21 of the first transistor T1, the first capacitor C1 may be provided by an area where the first capacitor electrode CAE1 and the second capacitor electrode CAE2 overlap each other.

A portion of the first power line VDL may be disposed on the second source drain conductive layer SDCDL2 on the first planarization layer 127.

In order for the first power ELVDD to be applied with a relatively uniform resistance across the entirety of the display area DA, the first power line VDL may be disposed as a mesh-shaped line in the display area DA.

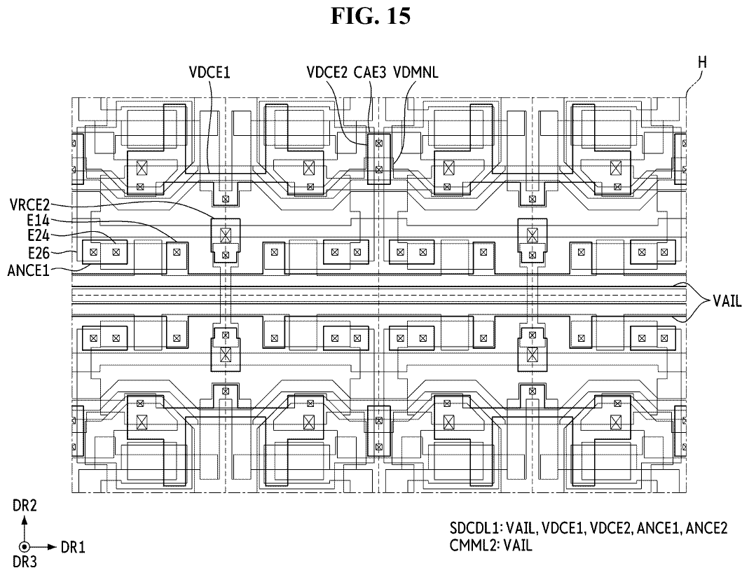

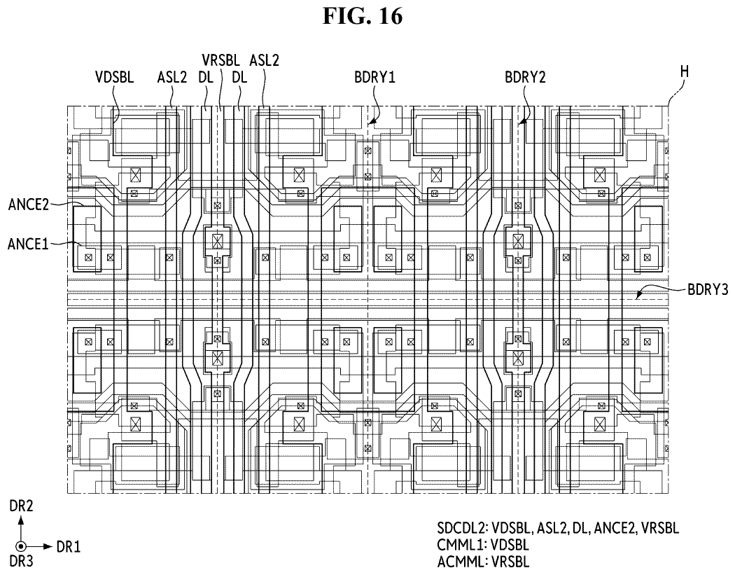

That is, the first power line VDL may include a first power main line (VDMNL in FIG. 15) disposed on the third gate conductive layer GCDL3 and extending in the first direction DR1, and a first power sub-line (VDSBL in FIG. 16) disposed on the second source drain conductive layer SDCDL2 and extending in the second direction DR2.

Each of the light-emitting pixel drivers EPD of the circuit layer 120 may further include a third capacitor electrode CAE3 disposed in the first gate conductive layer GCDL1, spaced apart from the first capacitor electrode CAE1, and electrically connected to the first power line VDL.

The second capacitor electrode CAE2 may overlap the first capacitor electrode CAE1 and the third capacitor electrode CAE3.

In addition, an electrode extending portion E16′ protruding from the first electrode E16 of the sixth transistor T6 may overlap the first capacitor electrode CAE1 and the third capacitor electrode CAE3.

Accordingly, the first capacitor C1 may also be provided by an area where the electrode extending portion E16′ and the first capacitor electrode CAE1 overlap each other.

In addition, the second capacitor C2 may be provided by areas where each of the second capacitor electrode CAE2 and the electrode extending portion E16′ and the third capacitor electrode CAE3 overlap each other.

The second electrode E26 of the sixth transistor T6 may be electrically connected to the anode electrode 131 of the light-emitting element LE through a first anode connection electrode ANCE1 and a second anode connection electrode ANCE2.

The first anode connection electrode ANCE1 may be disposed on the first source drain conductive layer SDCDL1 on the second inter-insulating layer 126, and may be electrically connected to the second electrode E26 of the sixth transistor T6 through a first anode contact hole ANCH1.

The first anode contact hole ANCH1 may penetrate through the second inter-insulating layer 126, the third gate insulating layer 125, the first inter-insulating layer 124, the second gate insulating layer 123, and the first gate insulating layer 122.

The second anode connection electrode ANCE2 may be disposed on the second source drain conductive layer SDCDL2 on the first planarization layer 127, and may be electrically connected to the first anode connection electrode ANCE1 through a second anode contact hole ANCH2 penetrating through the first planarization layer 127.

The anode electrode 131 may be disposed on the second planarization layer 128, and may be electrically connected to the second anode connection electrode ANCE2 through a third anode contact hole ANCH3 penetrating through the second planarization layer 128.

The element layer 130 may be disposed on the circuit layer 120 and may include light-emitting elements LE respectively corresponding to the light-emitting areas EA.

Each of the light-emitting elements LE may include an anode electrode 131 and a cathode electrode 134 that face each other, and a light-emitting layer 133 disposed therebetween.

That is, the element layer 130 may include anode electrodes 131 disposed in the light-emitting areas EA, a pixel defining layer 132 disposed in the non-light-emitting area and covering an edge of the anode electrode 131, light-emitting layers 133 disposed on the anode electrodes 131, and a cathode electrode 134 disposed on the light-emitting layers 133 and the pixel defining layer 132.

The pixel defining layer 132 may include a first pixel defining layer 1321 disposed on the second planarization layer 128, a second pixel defining layer 1322 disposed on the first pixel defining layer 1321, and a spacer layer 1323 disposed on a portion of the second pixel defining layer 1322.

In an embodiment, the first pixel defining layer 1321 may include a light-absorbing insulating material that absorbs light or a light-blocking insulating material that blocks light.

In an alternative embodiment, each of the light-emitting elements LE may further include a first common layer disposed between the anode electrode 131 and the light-emitting layer 133, and a second common layer disposed between the light-emitting layer 133 and the cathode electrode 134.

The anode electrode 131 may be disposed in each of the light-emitting areas EA and may be electrically connected to one light-emitting pixel driver EPD of the circuit layer 120. Such an anode electrode 131 may be also referred to as a pixel electrode.

The light-emitting layer 133 may include an organic light-emitting material that converts electron-hole pairs into light.

The cathode electrode 134 may be disposed in the display area DA including the light-emitting areas EA. The second power (ELVSS in FIG. 5) may be commonly applied to the cathode electrode 134. Such a cathode electrode 134 may be also referred to as a common electrode.

The sealing layer 140 may be disposed on the circuit layer 120 and cover the element layer 130.

In an embodiment, the sealing layer 140 may include a first sealing layer disposed on the element layer 130 and including or consisting of an inorganic insulating material, a second sealing layer disposed on the first sealing layer, overlapping the element layer 130, and including or consisting of an organic insulating material, and a third sealing layer disposed on the first sealing layer, covering the second sealing layer, and including or consisting of an inorganic insulating material.

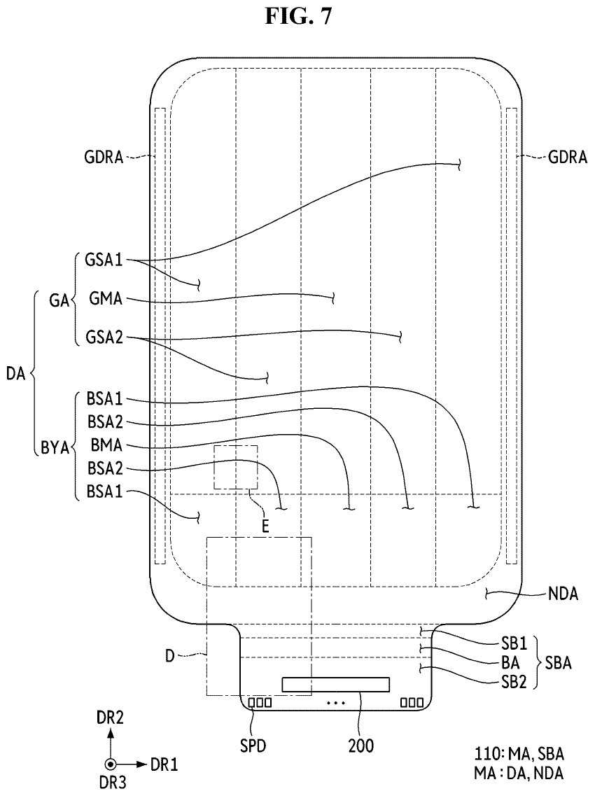

FIG. 7 is a plan view illustrating an embodiment of a substrate of FIG. 3.

Referring to FIG. 7, the substrate 110 of the display device 100 in embodiments may include a main area MA corresponding to a display surface and a sub-area SBA protruding from a portion of one side of the main area MA.

The main area MA includes a display area DA disposed at most of the center and a non-display area NDA disposed at an edge and surrounding the display area DA.

The display area DA may include a bypass area BYA disposed on one side next (adjacent) to the sub-area SBA, and a general area GA disposed in the remaining area excluding the bypass area BYA.

The bypass area BYA may include a bypass middle area BMA disposed at the center in the first direction DR1, a first bypass side area BSA1 parallel to the bypass middle area BMA in the first direction DR1 and in contact with the non-display area NDA, and a second bypass side area BSA2 disposed between the bypass middle area BMA and the first bypass side area BSA1.

The first bypass side area BSA1 may be next (adjacent) to a bent edge of the substrate 110 compared to the bypass middle area BMA and the second bypass side area BSA2.

The first bypass side area BSA1 and the second bypass side area BSA2 may be disposed between each side of the bypass middle area BMA in the first direction DR1 and the non-display area NDA.

The general area GA may include a general middle area GMA extended to the bypass middle area BMA of the bypass area BYA in the second direction DR2, a first general side area GSA1 extended to the first bypass side area BSA1 of the bypass area BYA in the second direction DR2, and a second general side area GSA2 extended to the second bypass side area BSA2 of the bypass area BYA in the second direction DR2.

The non-display area NDA may include a gate driving circuit area GDRA where a gate driving circuit is disposed.

The gate driving circuit area GDRA may face one side of the display area DA extending in the second direction DR2 in the non-display area NDA. However, this is merely one of embodiments, and the gate driving circuit area GDRA may be separately disposed in the display area DA rather than the non-display area NDA.

The gate driving circuit in the gate driving circuit area GDRA may sequentially transmit gate signals to gate lines. Here, the gate lines may include the scan write line (GWL in FIG. 5) that transmits the scan write signal (GW in FIG. 5), the reset control line (GRL in FIG. 5) that transmits the reset control signal (GR in FIG. 5), the bias control line (GBL in FIG. 5) that transmits the bias control signal (GB in FIG. 5), the first emission control line (ECL1 in FIG. 5) that transmits the first emission control signal (EC1 in FIG. 5), and the second emission control line (ECL2 in FIG. 5) that transmits the second emission control signal (EC2 in FIG. 5).

The sub-area SBA may include a bending area BA that is deformed into a bent shape, a first sub-area SB1 disposed between one side of the bending area BA and the main area MA, and a second sub-area SB2 connected to an opposite side of the bending area BA.

When the bending area BA is deformed into the bent shape, the second sub-area SB2 is disposed below the substrate 110 and overlaps the main area MA.

The display driving circuit 200 may be disposed in the second sub-area SB2.

Signal pads SPD bonded to the circuit board (300 in FIG. 3) may be arranged at one edge of the second sub-area SB2.

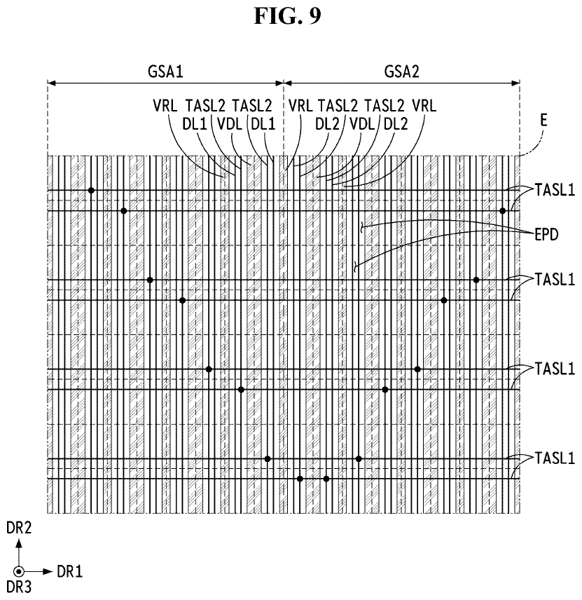

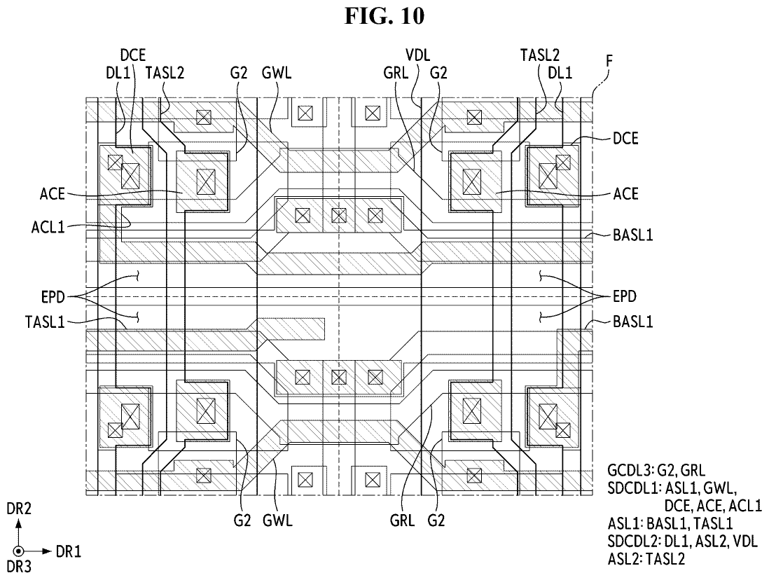

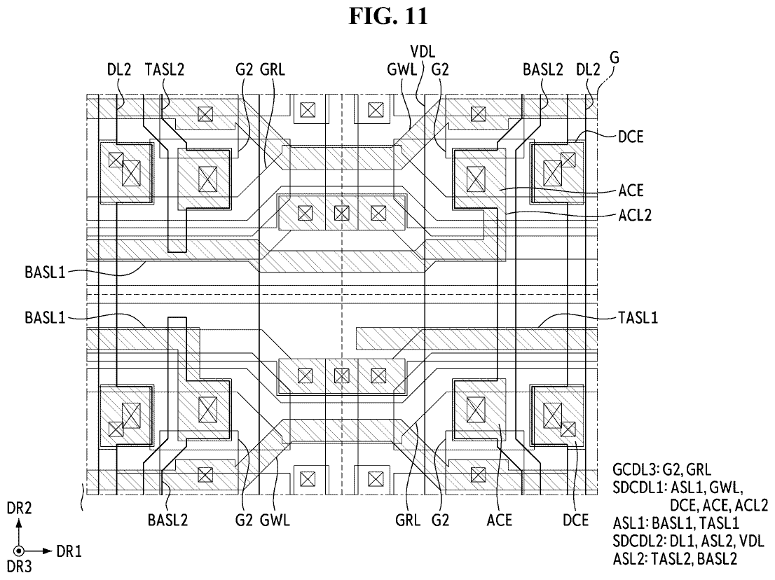

FIG. 8 is a plan view illustrating an embodiment of a circuit layer of portion D of FIG. 7. FIG. 9 is a plan view illustrating a circuit layer of portion E of FIG. 7. FIG. 10 is a plan view illustrating an embodiment of portion F of FIG. 8. FIG. 11 is a plan view illustrating an embodiment of portion G of FIG. 8.

Referring to FIGS. 8 and 9, the circuit layer (120 in FIG. 3) of the display device 100 in embodiments may include light-emitting pixel drivers EPD electrically connected to the light-emitting elements (LE in FIG. 5) of the element layer (130 in FIG. 3) and arranged parallel to each other in the first direction DR1 and the second direction DR2, data lines DL extending in the second direction DR2 and transmitting the data signals (Vdata in FIG. 5) to the light-emitting pixel drivers EPD, first auxiliary lines ASL1 extending in the first direction DR1, and second auxiliary lines ASL2 extending in the second direction DR2 and next (adjacent) to the data lines DL.

The first auxiliary lines ASL1 may include a first bypass auxiliary line BASL1 electrically connected to a first data line DL1 next (adjacent) to the non-display area NDA in the first direction DR1 among the data lines DL, and the remaining first transmission auxiliary lines TASL1 excluding the first bypass auxiliary line BASL1.

The second auxiliary lines ASL2 may include a second bypass auxiliary line BASL2 electrically connected to the first bypass auxiliary line BASL1, and the remaining second transmission auxiliary lines TASL2 excluding the second bypass auxiliary line BASL2.

The second bypass auxiliary line BASL2 may be next (adjacent) to the second data line DL2 that is spaced further from the non-display area NDA than the first data line DL1 in the first direction DR1 among the data lines DL.

The first data line DL1 may be disposed in the first bypass side area BSA1.

The second data line DL2 and the second bypass auxiliary line BASL2 may be disposed in the second bypass side area BSA2.

The first bypass auxiliary line BASL1 may be disposed in the first bypass side area BSA1 and the second bypass side area BSA2.

As illustrated in FIG. 8, in embodiments, the circuit layer 120 may further include data supply lines DSPL disposed in the non-display area NDA and electrically connected between the display driving circuit 200 and the data lines DL.

The data supply lines DSPL may be extended to the bypass middle area BMA and the second bypass side area BSA2.

The data supply lines DSPL may include a first data supply line DSPL1 that transmits a data signal of the first data line DL1, and a second data supply line DSPL2 that transmits a data signal of the second data line DL2.

The first data supply line DSPL1 may be extended to the second bypass auxiliary line BASL2 of the second bypass side area BSA2, and may be electrically connected to the first data line DL1 through the second bypass auxiliary line BASL2 and the first bypass auxiliary line BASL1.

The second data supply line DSPL2 may be extended to the second bypass side area BSA2 and directly electrically connected to the second data line DL2.

In this way, since the first data supply line DSPL1 is extended to the second bypass auxiliary line BASL2 of the second bypass side area BSA2, not to the first data line DL1 of the first bypass side area BSA1, an extension length of the first data supply line DSPL1 may be shortened. As a result, a width of an area desired for the arrangement of the data supply lines DSPL may be reduced, and thus a width of the non-display area NDA may be reduced.

In addition, since the data supply lines DSPL are not disposed in some areas next (adjacent) to the bent edges of the substrate 110 in the non-display area NDA, and thus the width of the non-display area NDA may be further reduced.

The data lines DL may further include a third data line DL3 disposed in the bypass middle area BMA. In addition, the data supply lines DSPL may further include a third data supply line DSPL3 that transmits a data signal of the third data line DL3.

The third data supply line DSPL3 may extend to the bypass middle area BMA and may be directly electrically connected to the third data line DL3.

The first bypass auxiliary line BASL1 may be disposed between the first data line DL1 and the second bypass auxiliary line BASL2.

The second bypass auxiliary line BASL2 may be disposed between the first data supply line DSPL1 and the first bypass auxiliary line BASL1 in the non-display area NDA.

In this way, since the first bypass auxiliary line BASL1 and the second bypass auxiliary line BASL2 are exclusively disposed in the bypass area BYA, and ends of the first bypass auxiliary line BASL1 and ends of the second bypass auxiliary line BASL2 are disposed in the display area DA, the visibility of the first bypass auxiliary line BASL1 and the second bypass auxiliary line BASL2 may be improved.

To prevent this, the first auxiliary lines ASL1 may further include the first transmission auxiliary lines TASL1 as well as the first bypass auxiliary line BASL1. In addition, the second auxiliary lines ASL2 may further include the second transmission auxiliary lines TASL2 as well as the second bypass auxiliary line BASL2.

Two of the first transmission auxiliary lines TASL1 may be extended from opposite ends of the first bypass auxiliary line BASL1 to the non-display area NDA.

One of the second transmission auxiliary lines TASL2 may be extended from one end of the second bypass auxiliary line BASL2 to the non-display area NDA in a direction away from the sub-area SBA.

Since the second bypass auxiliary line BASL2 is disposed only in the second bypass side area BSA2, each of the first data line DL1 of the first bypass side area BSA1 and the third data line DL3 of the bypass middle area BMA may be entirely next (adjacent) to the second transmission auxiliary lines TASL2.

In embodiments, each of the first transmission auxiliary lines TASL1 and the second transmission auxiliary lines TASL2 may be electrically connected to one of the first power line (VDL in FIG. 5) that transmits the first power (ELVDD in FIG. 5), the second power line that transmits the second power (ELVSS in FIG. 5), the initialization voltage line (VAIL in FIG. 5) that transmits the initialization voltage (VAINT in FIG. 5), and the reference voltage line (VRL in FIG. 5) that transmits the reference voltage (VREF in FIG. 5). In this way, resistance of a path through which the power or constant voltage is transmitted may be reduced by the first transmission auxiliary lines TASL1 and the second transmission auxiliary lines TASL2.

In embodiments, the circuit layer 120 may further include a first power supply line VDSPL and a second power supply line VSSPL that are disposed in the non-display area NDA and extend to the sub-area SBA.

The first power supply line VDSPL transmits the first power (ELVDD in FIG. 5), and the second power supply line VSSPL transmits the second power (ELVSS in FIG. 5).

The first power supply line VDSPL may be electrically connected to a first power pad for transmitting the first power (ELVDD in FIG. 5) among the signal pads (SPD in FIG. 7) disposed in the second sub-area SB2.

The second power supply line (VSSPL in FIG. 5) may be electrically connected to a second power pad for transmitting the second power (ELVSS in FIG. 5) among the signal pads (SPD in FIG. 7) disposed in the second sub-area SB2.

In an embodiment, at least some of the first transmission auxiliary lines TASL1 may be electrically connected to the second power supply line VSSPL.

In addition, at least some of the second transmission auxiliary lines TASL2 may be electrically connected to at least some of the first transmission auxiliary lines TASL1 and to the second power supply line VSSPL.

In embodiments, the circuit layer 120 may further include first power lines VDL that transmit the first power (ELVDD in FIG. 5) to the light-emitting pixel drivers EPD.

The first power lines VDL may extend in the second direction DR2 and be electrically connected to the first power supply line VDSPL.

The first power lines VDL may be disposed between two second auxiliary lines ASL2 that are next (adjacent) to each other in the first direction DR1.

In embodiments, the circuit layer 120 may further include reference voltage lines VRL that transmit the reference voltage (VREF in FIG. 5) to the light-emitting pixel drivers EPD.

The reference voltage lines VRL may extend in the second direction DR2.

The reference voltage lines VRL may be disposed between two data lines DL that are next (adjacent) to each other in the first direction DR1.

As illustrated in FIG. 9, the first transmission auxiliary lines TASL1 of the first auxiliary lines ASL1 and the second transmission auxiliary lines TASL2 of the second auxiliary lines ASL2 may be disposed in the general area GA.

Each of the first transmission auxiliary lines TASL1 may be electrically connected to at least some of the second transmission auxiliary lines TASL2.

As illustrated in FIGS. 8 and 9, in embodiments, two of the first auxiliary lines ASL1 may be next (adjacent) to a boundary between two light-emitting pixel drivers EPD that are next (adjacent) to each other in the first direction DR1.

As illustrated in FIGS. 10 and 11, the second source drain conductive layer SDCDL2 may include data lines DL and second auxiliary lines ASL2.

The data lines DL may include a first data line DL1 in the first bypass side area BSA1, and a second data line DL2 in the second bypass side area BSA2.

The second auxiliary lines ASL2 may include the second bypass auxiliary line BASL2 that transmits the data signal of the first data line DL1, and the remaining second transmission auxiliary lines TASL2 excluding the second bypass auxiliary line BASL2.

The second bypass auxiliary line BASL2 may be next (adjacent) to the second data line DL2.

The second source drain conductive layer SDCDL2 may further include a portion of the first power line VDL.

The first source drain conductive layer SDCDL1 may include first auxiliary lines ASL1.

The first auxiliary lines ASL1 may include the first bypass auxiliary line BASL1 that transmits the data signal of the first data line DL1, and the remaining first transmission auxiliary lines TASL1 excluding the first bypass auxiliary line BASL1.

The first source drain conductive layer SDCDL1 may further include data connection electrodes DCE overlapping protruding portions of the data lines DL, and auxiliary connection electrodes ACE overlapping protruding portions of the second auxiliary lines ASL2.

The data connection electrodes DCE and the auxiliary connection electrodes ACE may be spaced apart from the first auxiliary lines ASL1.

The data connection electrodes DCE overlapping one of the data lines DL may be electrically connected to one data line DL through each data additional connection hole (DCAH in FIG. 6).

At least one of the auxiliary connection electrodes ACE overlapping one of the second auxiliary lines ASL2 may be electrically connected to one second auxiliary line ASL2 through an auxiliary connection hole.

The first source drain conductive layer SDCDL1 may further include a scan write line GWL extending in the first direction DR1 and transmitting the scan write signal (GW in FIG. 5).

As illustrated in FIG. 10, the first source drain conductive layer SDCDL1 may further include a first auxiliary connection line ACL1 extending from one first bypass auxiliary line BASL1 in the second direction DR2 and connected to one of the data connection electrodes DCE overlapping one first data line DL1.

Accordingly, one first data line DL1 may be electrically connected to one first bypass auxiliary line BASL1 through one first auxiliary connection line ACL1, one data connection electrode DCE, and the data additional connection hole DCAH.

The first source drain conductive layer SDCDL1 may further include a second auxiliary connection line ACL2 extending from one first bypass auxiliary line BASL1 in the second direction DR2 and connected to one of the auxiliary connection electrodes ACE overlapping one second bypass auxiliary line BASL2.

Accordingly, one second bypass auxiliary line TASL2 may be electrically connected to one first bypass auxiliary line BASL1 through the second auxiliary connection line ACL2, one auxiliary connection electrode ACE, and the auxiliary connection hole.

Furthermore, as illustrated in FIGS. 10 and 11, in embodiments, the third gate conductive layer GCDL3 may further include a gate electrode G2 of the second transistor T2 and a reset control line GRL.

The gate electrode G2 of the second transistor T2 may be electrically connected to the scan write line GWL disposed on the first source drain conductive layer SDCDL1 through a connection hole.

FIG. 12 is a plan view illustrating an embodiment of a first semiconductor layer and a second semiconductor layer of portion C of FIG. 4.

As illustrated in FIG. 12, in embodiments, the circuit layer 120 may include light-emitting pixel drivers EPD arranged in the first direction DR1 and the second direction DR2, a first semiconductor layer SEL1 disposed on the substrate (110 in FIG. 6), and a second semiconductor layer SEL2 disposed on one or more insulating layers (the first gate insulating layer 122, the second gate insulating layer 123, and the first inter-insulating layer 124 in FIG. 6) covering the first semiconductor layer SEL1.

The light-emitting pixel drivers EPD may include a first pixel driver (hereinafter also referred to as “first light-emitting pixel driver”) EPD1 and a second pixel driver (hereinafter also referred to as “second light-emitting pixel driver”) EPD2 that are next (adjacent) to each other in the first direction DR1.

A first semiconductor layer SEL1 and a second semiconductor layer SEL2 of the first light-emitting pixel driver EPD1 may be symmetrical with a first semiconductor layer SEL1 and a second semiconductor layer SEL2 of the second light-emitting pixel driver EPD2 based on a first boundary BDRY1 between the first light-emitting pixel driver EPD1 and the second light-emitting pixel driver EPD2.

The light-emitting pixel drivers EPD may further include a third light-emitting pixel driver EPD3 next (adjacent) to the second light-emitting pixel driver EPD2 in the first direction DR1, a fourth light-emitting pixel driver EPD4 next (adjacent) to the first light-emitting pixel driver EPD1 in the second direction DR2, a fifth light-emitting pixel driver EPD5 next (adjacent) to the second light-emitting pixel driver EPD2 in the second direction DR2, and a sixth light-emitting pixel driver EPD6 next (adjacent) to the third light-emitting pixel driver EPD3 in the second direction DR2.

The first semiconductor layer SEL1 and the second semiconductor layer SEL2 of the second light-emitting pixel driver EPD2 may be symmetrical with a first semiconductor layer SEL1 and a second semiconductor layer SEL2 of the third light-emitting pixel driver EPD3 based on a second boundary BDRY2 between the second light-emitting pixel driver EPD2 and the third light-emitting pixel driver EPD3.

The first semiconductor layer SEL1 and the second semiconductor layer SEL2 of the first light-emitting pixel driver EPD1 may be symmetrical with a first semiconductor layer SEL1 and a second semiconductor layer SEL2 of the fourth light-emitting pixel driver EPD4 based on a third boundary BDRY3 between the first light-emitting pixel driver EPD1 and the fourth light-emitting pixel driver EPD4.

The first semiconductor layer SEL1 and the second semiconductor layer SEL2 of the second light-emitting pixel driver EPD2 may be symmetrical with a first semiconductor layer SEL1 and a second semiconductor layer SEL2 of the fifth light-emitting pixel driver EPD5 based on an extension line of the third boundary BDRY3.

The first semiconductor layer SEL1 and the second semiconductor layer SEL2 of the third light-emitting pixel driver EPD3 may be symmetrical with a first semiconductor layer SEL1 and a second semiconductor layer SEL2 of the sixth light-emitting pixel driver EPD6 based on the extension line of the third boundary BDRY3.

Accordingly, the first semiconductor layer SEL1 and the second semiconductor layer SEL2 of the fourth light-emitting pixel driver EPD4 may be symmetrical with the first semiconductor layer SEL1 and the second semiconductor layer SEL2 of the fifth light-emitting pixel driver EPD5 based on an extension line of the first boundary BDRY1.

In addition, the first semiconductor layer SEL1 and the second semiconductor layer SEL2 of the fifth light-emitting pixel driver EPD5 may be symmetrical with the first semiconductor layer SEL1 and the second semiconductor layer SEL2 of the sixth light-emitting pixel driver EPD6 based on an extension line of the second boundary BDRY2.

The first semiconductor layer SEL1 may include a channel portion CH5, a first electrode E15, and a second electrode E25 of the fifth transistor T5, and a channel portion CH6, a first electrode E16, and a second electrode E26 of the sixth transistor T6.

The second semiconductor layer SEL2 may include a channel portion CH1, a first electrode E11, and a second electrode E21 of the first transistor T1, a channel portion CH2, a first electrode E12, and a second electrode E22 of the second transistor T2, a channel portion CH3, a first electrode E13, and a second electrode E23 of the third transistor T3, and a channel portion CH4, a first electrode E14, and a second electrode E24 of the fourth transistor T4.

The first electrode E11 of the first transistor T1 may be connected to one side of the channel portion CH1 of the first transistor T1, and may be next (adjacent) to the first electrode E15 of the fifth transistor T5.

The second electrode E21 of the first transistor T1 may be connected to an opposite side of the channel portion CH1 of the first transistor T1, and may be next (adjacent) to the first electrode E16 of the sixth transistor T6.

The second electrode E22 of the second transistor T2 may be connected to the second electrode E23 of the third transistor T3.

The second electrode E24 of the fourth transistor T4 may be next (adjacent) to the second electrode E26 of the sixth transistor T6.

In the second light-emitting pixel driver EPD2 and the third light-emitting pixel driver EPD3 next (adjacent) to each other in the first direction DR1, the fifth transistors T5 may include the first electrodes E15 interconnected at the second boundary BDRY2.

FIG. 13 is a plan view illustrating a first semiconductor layer, a first gate conductive layer, and a second gate conductive layer of portion H of FIG. 12. FIG. 14 is a plan view illustrating a second semiconductor layer and a third gate conductive layer of portion H of FIG. 12. FIG. 15 is a plan view illustrating a first source drain conductive layer of portion H of FIG. 12. FIG. 16 is a plan view illustrating a second source drain conductive layer of portion H of FIG. 12.

FIGS. 13, 14, 15, and 16 illustrate a portion of each of the first light-emitting pixel driver EPD1, the second light-emitting pixel driver EPD2, the third light-emitting pixel driver EPD3, the fourth light-emitting pixel driver EPD4, the fifth light-emitting pixel driver EPD5, and the sixth light-emitting pixel driver EPD6 next (adjacent) to the points where each of the first boundary BDRY1 and the second boundary BDRY2 and the third boundary BDRY3 intersects.

In embodiments, the circuit layer 120 may include a first sharing line (CMML1 in FIG. 16) next (adjacent) to the first boundary BDRY1 between the first light-emitting pixel driver EPD1 and the second light-emitting pixel driver EPD2 and extending in the second direction DR2.

The first sharing line CMML1 may be electrically connected to the first light-emitting pixel driver EPD1 and the second light-emitting pixel driver EPD2, as well as the fourth light-emitting pixel driver EPD4 and the fifth light-emitting pixel driver EPD5 that are parallel to the first light-emitting pixel driver EPD1 and the second light-emitting pixel driver EPD2 in the second direction DR2.

In an embodiment, the first power line (VDL in FIG. 5) that transmits the first power (ELVDD in FIG. 5) may include a first power main line (VDMNL in FIG. 14) disposed on the third gate conductive layer (GCDL3 in FIG. 14) and extending in the first direction DR1, and a first power sub-line (VDSBL in FIG. 16) disposed on the second source drain conductive layer (SDCDL2 in FIG. 16) and extending in the second direction DR2.

The first sharing line CMML1 may include the first power sub-line (VDSBL in FIG. 16) that overlaps the first boundary BDRY1.

In an alternative embodiment, the circuit layer 120 may include an additional sharing line (ACMML in FIG. 16) next (adjacent) to the second boundary BDRY2 between the second light-emitting pixel driver EPD2 and the third light-emitting pixel driver EPD3 and extending in the second direction DR2.

The additional sharing line ACMML may be electrically connected to the second light-emitting pixel driver EPD2 and the third light-emitting pixel driver EPD3, as well as the fifth light-emitting pixel driver EPD5 and the sixth light-emitting pixel driver EPD6 that are parallel to the second light-emitting pixel driver EPD2 and the third light-emitting pixel driver EPD3 in the second direction DR2.

In an embodiment, the reference voltage line (VRL in FIG. 5) that transmits the reference voltage (VREF in FIG. 5) may include a reference voltage main line (VRMNL in FIG. 17) disposed on the second gate conductive layer (GCDL2 in FIG. 17) and extending in the first direction DR1, and a reference voltage sub-line (VRSBL in FIG. 16) disposed on the second source drain conductive layer (SDCDL2 in FIG. 16) and extending in the second direction DR2.

The additional sharing line ACMML may include the reference voltage sub-line (VRSBL in FIG. 16) that overlaps the second boundary BDRY2.

In embodiments, the circuit layer 120 may include at least one second sharing line (CMML2 in FIG. 14) next (adjacent) to the third boundary BDRY3 between the first light-emitting pixel driver EPD1 and the fourth light-emitting pixel driver EPD4 and extending in the first direction DR1.

The second sharing line CMML2 may be electrically connected to the first light-emitting pixel driver EPD1 and the fourth light-emitting pixel driver EPD4, as well as the second light-emitting pixel driver EPD2, the third light-emitting pixel driver EPD3, the fifth light-emitting pixel driver EPD5, and the sixth light-emitting pixel driver EPD6 that are parallel to the first light-emitting pixel driver EPD1 and the fourth light-emitting pixel driver EPD4 in the first direction DR1.

In an embodiment, at least one second sharing line CMML2 may include at least one of the bias control line (GBL in FIG. 14) that transmits the bias control signal (GB in FIG. 5) disposed on the third gate conductive layer (GCDL3 in FIG. 14) and the initialization voltage line (VAIL in FIG. 15) that is disposed on the first source drain conductive layer SDCDL1 in FIG. 15) and transmits the initialization voltage (VAINT in FIG. 5).

In an embodiment, when the bias control line GBL or the initialization voltage line (VAIL in FIG. 15) is at least one second sharing line CMML2, the bias control line GBL or the initialization voltage line (VAIL in FIG. 15) may overlap the third boundary BDRY3.

As illustrated in FIG. 13, the first semiconductor layer SEL1 may include a channel portion CH5, a first electrode E15, and a second electrode E25 of the fifth transistor T5, a channel portion CH6, a first electrode E16, and a second electrode E26 of the sixth transistor T6, and an electrode extending portion E16′ extending from the first electrode E16 of the sixth transistor T6.

In embodiments, the remaining portions of the first semiconductor layer SEL1 excluding the channel portion CH5 of the fifth transistor T5 and the channel portion CH6 of the sixth transistor T6 may be conductive by performing a process of injecting dopants using a separate mask prior to the process of disposing the first gate conductive layer GCDL1.

The first gate conductive layer GCDL1 may include a first emission control line ECL1 extending in the first direction DR1 and intersecting the channel portion CH5 of the fifth transistor T5, a second emission control line ECL2 extending in the first direction DR1 and intersecting the channel portion CH6 of the sixth transistor T6, and a first capacitor electrode CAE1 and a third capacitor electrode CAE3 spaced apart from each other.

The gate electrode G5 of the fifth transistor T5 may be provided as a portion of the first emission control line ECL1 that intersects the channel portion CH5 of the fifth transistor T5.

The gate electrode G6 of the sixth transistor T6 may be provided as a portion of the second emission control line ECL2 that intersects the channel portion CH6 of the sixth transistor T6.

The first capacitor electrode CAE1 may overlap a portion of the electrode extending portion E16′.

The first capacitor electrode CAE1 may be electrically connected to the gate electrode G1 of the first transistor T1 through the first node connection electrode NCE1.

The third capacitor electrode CAE3 may overlap another portion of the electrode extending portion E16′.

The third capacitor electrode CAE3 of the first light-emitting pixel driver EPD1 and the third capacitor electrode CAE3 of the second light-emitting pixel driver EPD2 may be connected to each other at the first boundary BDRY1.

The third capacitor electrodes CAE3 disposed in the first light-emitting pixel driver EPD1 and the second light-emitting pixel driver EPD2 next (adjacent) to each other in the first direction DR1 may be connected to each other at the first boundary BDRY1.

The second gate conductive layer GCDL2 may include a second capacitor electrode CAE2.

The second capacitor electrode CAE2 may overlap the first capacitor electrode CAE1 and the third capacitor electrode CAE3.

The second capacitor electrode CAE2 may be electrically connected to the second electrode E21 of the first transistor T1 through the second node connection electrode NCE2.

The second gate conductive layer GCDL2 may further include a first reference voltage connection electrode VRCE1.

The first reference voltage connection electrode VRCE1 may be parallel to the second boundary BDRY2 and may intersect the extension line of the third boundary BDRY3.

As illustrated in FIG. 14, the second semiconductor layer SEL2 may include the channel portion CH1, the first electrode E11, and the second electrode E21 of the first transistor T1, and the channel portion CH4, the first electrode E14, and the second electrode E24 of the fourth transistor T4.

The third gate conductive layer GCDL3 may include the gate electrode G1 of the first transistor T1 overlapping the channel portion CH1 of the first transistor T1, the first power main line VDMNL that extends in the first direction DR1 and transmits the first power (ELVDD in FIG. 5), and the bias control line GBL that extends in the first direction DR1 and transmits the bias control signal (GB in FIG. 5).

The first power main line VDMNL may intersect the third capacitor electrode (CAE3 in FIG. 13) and be electrically connected to the third capacitor electrode CAE3 through a connection hole.

In embodiments, the bias control line GBL may overlap the third boundary BDRY3.

In addition, the bias control line GBL may include protruding portions protruding on opposite sides in the second direction DR2. That is, the bias control line GBL may include the first light-emitting pixel driver EPD1 and the fourth light-emitting pixel driver EPD4 that contact the extension line of the third boundary BDRY3, and protruding portions overlapping the second light-emitting pixel driver EPD2, the third light-emitting pixel driver EPD3, the fifth light-emitting pixel driver EPD5, and the sixth light-emitting pixel driver EPD6 that are parallel to include the first light-emitting pixel driver EPD1 and the fourth light-emitting pixel driver EPD4 in the first direction DR1.

Accordingly, at least one second sharing line CMML2 electrically connected to the first light-emitting pixel driver EPD1, the second light-emitting pixel driver EPD2, the third light-emitting pixel driver EPD3, the fourth light-emitting pixel driver EPD4, the fifth light-emitting pixel driver EPD5, and the sixth light-emitting pixel driver EPD6 may include the bias control line GBL.

The protruding portion of the bias control line GBL may be the gate electrode G4 of the fourth transistor T4 that overlaps the channel portion CH4 of the fourth transistor T4.

As illustrated in FIG. 15, the first source drain conductive layer SDCDL1 may include a first power connection auxiliary electrode VDCE1, a second power connection auxiliary electrode VDCE2, a first anode connection electrode ANCE1, a second reference voltage connection electrode VRCE2, and an initialization voltage line VAIL.

The first power connection auxiliary electrode VDCE1 may be electrically connected to the third capacitor electrode (CAE3 in FIG. 13) and the first power main line (VDMNL in FIG. 14).

As a result, the third capacitor electrode (CAE3 in FIG. 13) may be electrically connected to the first power main line VDMNL through the first power connection auxiliary electrode VDCE1.

The first power connection auxiliary electrode VDCE1 of the second light-emitting pixel driver EPD2 and the first power connection auxiliary electrode VDCE1 of the third light-emitting pixel driver EPD3 may be connected to each other at the second boundary BDRY2.

The second power connection auxiliary electrode VDCE2 may be electrically connected to the first power main line VDMNL and the first electrode E15 of the fifth transistor T5.

As a result, the first electrode E15 of the fifth transistor T5 may be electrically connected to the first power main line VDMNL through the second power connection auxiliary electrode VDCE2.

The second power connection auxiliary electrode VDCE2 of the first light-emitting pixel driver EPD1 and the second power connection auxiliary electrode VDCE2 of the second light-emitting pixel driver EPD2 may be connected to each other at the first boundary BDRY1.

The first anode connection electrode ANCE1 may be electrically connected to the second electrode E24 of the fourth transistor T4 and the second electrode E26 of the sixth transistor T6.

The second reference voltage connection electrode VRCE2 may overlap the second boundary BDRY2 and be electrically connected to the first reference voltage connection electrode VRCE1.

The initialization voltage line VAIL may overlap the third boundary BDRY3.

The initialization voltage line VAIL may include protruding portions that protrude on opposite sides in the second direction DR2 and overlap the first electrode E14 of the fourth transistor T4. That is, the initialization voltage line VAIL may include the first light-emitting pixel driver EPD1 and the fourth light-emitting pixel driver EPD4 that contact the extension line of the third boundary BDRY3, and protruding portions overlapping the second light-emitting pixel driver EPD2, the third light-emitting pixel driver EPD3, the fifth light-emitting pixel driver EPD5, and the sixth light-emitting pixel driver EPD6 that are parallel to include the first light-emitting pixel driver EPD1 and the fourth light-emitting pixel driver EPD4 in the first direction DR1.

Accordingly, at least one second sharing line CMML2 electrically connected to the first light-emitting pixel driver EPD1, the second light-emitting pixel driver EPD2, the third light-emitting pixel driver EPD3, the fourth light-emitting pixel driver EPD4, the fifth light-emitting pixel driver EPD5, and the sixth light-emitting pixel driver EPD6 may include the initialization voltage line VAIL.

The initialization voltage line VAIL may be electrically connected to the first electrode E14 of the fourth transistor T4 through a connection hole overlapping the protruding portion.

As illustrated in FIG. 16, the second source drain conductive layer SDCDL2 may include a data line DL, a second auxiliary line ASL2, a first power sub-line VDSBL, a reference voltage sub-line VRSBL, and a second anode connection electrode ANCE2.

Each of the data line DL, the second auxiliary line ASL2, the first power sub-line VDSBL, and the reference voltage sub-line VRSBL may extend in the second direction DR2.

The second anode connection electrode ANCE2 may be electrically connected to the first anode connection electrode ANCE1.

The first power sub-line VDSBL may be electrically connected to the first power main line (VDMNL in FIG. 14) through the first power connection auxiliary electrode VDCE1.

The first power sub-line VDSBL may overlap the first boundary BDRY1 and be next (adjacent) to the second auxiliary lines ASL2.

The first power sub-line VDSBL may be electrically connected to the first light-emitting pixel driver EPD1 and the second light-emitting pixel driver EPD2 that contact the first boundary BDRY1, as well as the fourth light-emitting pixel driver EPD4 and the fifth light-emitting pixel driver EPD5 that are parallel to the first light-emitting pixel driver EPD1 and the second light-emitting pixel driver EPD2 in the second direction DR2.

In other words, the first sharing line CMML1 electrically connected to the first light-emitting pixel driver EPD1, the second light-emitting pixel driver EPD2, the fourth light-emitting pixel driver EPD4, and the fifth light-emitting pixel driver EPD5 may include the first power sub-line VDSBL.

In this way, the first power (ELVDD in FIG. 5) may be transmitted not only to the first power main line (VDMNL in FIG. 14), but also to the light-emitting pixel drivers EPD in the display area DA in a mesh form including the first power main line VDMNL and the first power sub-line VDSBL. Accordingly, the delay or voltage drop of the first power ELVDD due to line resistance may be reduced.

In addition, in embodiments, the first sharing line CMML1 including the first power sub-line VDSBL is electrically connected to two pixel columns next (adjacent) to each other in the first direction DR1 among the pixel columns each composed of the pixel drivers EPD arranged in parallel in the second direction DR2 in the display area DA.

Accordingly, the total number of first power sub-lines VDSBL disposed in the display area DA may be reduced to half the number of pixel columns, a width of the display area DA consumed for the arrangement of the first power sub-line VDSBL may be reduced. Therefore, this may be advantageous in increasing a resolution of the display device 100.

The reference voltage sub-line VRSBL may be electrically connected to the second reference voltage connection electrode (VRCE2 in FIG. 15).

The reference voltage sub-line VRSBL may overlap the second boundary BDRY2 and be next (adjacent) to the data lines DL.

That is, the reference voltage sub-line VRSBL may be electrically connected to the second light-emitting pixel driver EPD2 and the third light-emitting pixel driver EPD3 that contact the second boundary BDRY2, and the fifth light-emitting pixel driver EPD5 and the sixth light-emitting pixel driver EPD6 that are parallel to the second light-emitting pixel driver EPD2 and the third light-emitting pixel driver EPD3 in the second direction DR2.

In other words, the addition sharing line ACMML electrically connected to the second light-emitting pixel driver EPD2, the third light-emitting pixel driver EPD3, the fifth light-emitting pixel driver EPD5, and the sixth light-emitting pixel driver EPD6 may include the reference voltage sub-line VRSBL.

In this way, the reference voltage (VREF in FIG. 5) may be transmitted to the light-emitting pixel drivers EPD in the display area DA in a mesh form including the reference voltage sub-line VRSBL, and the total number of reference voltage sub-lines VRSBL disposed in the display area DA may be reduced to half the number of pixel columns. Therefore, since a width of the display area DA consumed for the arrangement of the reference voltage sub-line VRSBL may be reduced, it may be advantageous in increasing the resolution of the display device 100.

As described above, as the circuit layer 120 of the display device 100 in embodiments includes the first sharing line CMML1 electrically connected to the light-emitting pixel drivers EPD next (adjacent) to each other in the first direction DR1, and at least one second sharing line CMML2 electrically connected to the light-emitting pixel drivers EPD next (adjacent) to each other in the second direction DR2, it may be advantageous in increasing the resolution of the display device 100.

FIG. 17 is a plan view illustrating an embodiment of a second gate conductive layer, a second semiconductor layer, and a third gate conductive layer of portion I of FIG. 12.

Since a display device 100 in an embodiment illustrated in FIG. 17 is substantially the same as the display device 100 in the embodiments illustrated in FIGS. 1 to 16 except that the circuit layer 120 further includes at least one third sharing line CMML3 next (adjacent) to the fourth boundary BDRY4, a duplicate description will be omitted below.

As illustrated in FIG. 17, in an embodiment, the circuit layer 120 may further include at least one third sharing line CMML3 extending in the first direction DR1 and next (adjacent) to the fourth boundary BDRY4.

At least one third sharing line CMML3 may extend in the first direction DR1 and be electrically connected to the fourth light-emitting pixel driver EPD4, the fifth light-emitting pixel driver EPD5, a seventh light-emitting pixel driver EPD7, and an eighth light-emitting pixel driver EPD8 that contact the fourth boundary BDRY4 and an extension line thereof.

In this way, the third sharing line CMML3 may be electrically connected to two pixel rows next (adjacent) to each other in the second direction among the pixel rows composed of the light-emitting pixel drivers EPD arranged in parallel in the first direction DR1 in the display area DA. Therefore, since the number of any one third sharing line CMML3 disposed in the display area DA may be reduced to half the number of pixel rows disposed in the display area DA, the width of the display area DA consumed for the arrangement of the third sharing lines CMML3 may be reduced. As a result, this may be advantageous in increasing the resolution of the display device 100.

As illustrated in FIG. 17, the second gate conductive layer GCDL2 may include a reference voltage main line VRMNL extending in the first direction DR1 and transmitting the reference voltage (VREF in FIG. 5).

The reference voltage main line VRMNL may be electrically connected to the reference voltage sub-line (VRSBL in FIG. 16) through the first reference voltage connection electrode (VRCE1 in FIG. 13) and the second reference voltage connection electrode (VRCE2 in FIG. 15).

In an embodiment, when the first reference voltage connection electrode (VRCE1 in FIG. 13) protrudes from the reference voltage main line VRMNL, the reference voltage main line VRMNL may be electrically connected to the reference voltage sub-line (VRSBL in FIG. 16) through the first reference voltage connection electrode (VRCE1 in FIG. 13) and the second reference voltage connection electrode (VRCE2 in FIG. 15).

In an embodiment, the reference voltage main line VRMNL may include protruding portions that overlap the fourth light-emitting pixel driver EPD4, the fifth light-emitting pixel driver EPD5, the seventh light-emitting pixel driver EPD7, and the eighth light-emitting pixel driver EPD8.

The reference voltage main line VRMNL may be electrically connected to the first electrode E13 of the third transistor T3 of each of the fourth light-emitting pixel driver EPD4, the fifth light-emitting pixel driver EPD5, the seventh light-emitting pixel driver EPD7, and the eighth light-emitting pixel driver EPD8 through a connection hole overlapping the protruding portion.

Accordingly, at least one third sharing line CMML3 electrically connected to the fourth light-emitting pixel driver EPD4, the fifth light-emitting pixel driver EPD5, the seventh light-emitting pixel driver EPD7, and the eighth light-emitting pixel driver EPD8 may include the reference voltage main line VRMNL.

The second semiconductor layer SEL2 may include a channel portion CH2, a first electrode E12, and a second electrode E22 of the second transistor T2, and a channel portion CH3, a first electrode E13, and a second electrode E23 of the third transistor T3.

The third gate conductive layer GCDL3 may include the gate electrode G2 of the second transistor T2 overlapping the channel portion CH2 of the second transistor T2, and the reset control line GRL that transmits the reset control signal (GR in FIG. 5).

The reset control line GRL may include a reset control main line GRMNL extending in the first direction DR1 and overlapping the fourth light-emitting pixel driver EPD4 and the fifth light-emitting pixel driver EPD5, a reset control protruding line GRPRL protruding from the reset control main line GRMNL and extending in the second direction DR2, and a reset control extension line GREXL connected to the reset control protruding line GRPRL, extending in the first direction DR1, and overlapping the seventh light-emitting pixel driver EPD7 and the eighth light-emitting pixel driver EPD8.

In each of the fourth light-emitting pixel driver EPD4 and the fifth light-emitting pixel driver EPD5, the gate electrode G3 of the third transistor T3 may be provided as a portion of the reset control main line GRMNL.

In addition, in each of the seventh light-emitting pixel driver EPD7 and the eighth light-emitting pixel driver EPD8, the gate electrode G3 of the third transistor T3 may be provided as a portion of the reset control extension line GREXL.

That is, the reset control line GRL may be electrically connected to the third transistors T3 disposed in the fourth light-emitting pixel driver EPD4, the fifth light-emitting pixel driver EPD5, the seventh light-emitting pixel driver EPD7, and the eighth light-emitting pixel driver EPD8. The third transistor T3 may be turned on by the reset control signal GR of the reset control line GRL.

Accordingly, at least one third sharing line CMML3 electrically connected to the fourth light-emitting pixel driver EPD4, the fifth light-emitting pixel driver EPD5, the seventh light-emitting pixel driver EPD7, and the eighth light-emitting pixel driver EPD8 may include the reset control line GRL.

Therefore, since the number of reset control lines GRL may be reduced to half the number of pixel rows, it may be advantageous in increasing the resolution of the display device 100.

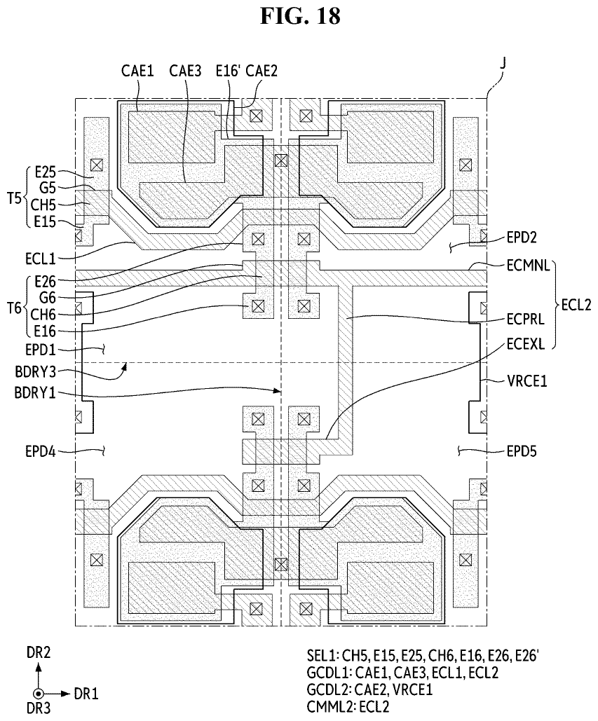

FIG. 18 is a plan view illustrating a first semiconductor layer, a first gate conductive layer, and a second gate conductive layer of portion J of FIG. 12.

Since a display device 100 in an embodiment illustrated in FIG. 18 is substantially the same as the display device 100 in the embodiments illustrated in FIGS. 1 to 17 except that the second sharing line CMML2 of the circuit layer 120 includes a second emission control line ECL2, a duplicate description will be omitted below.

In embodiments, the circuit layer 120 may include at least one second sharing line CMML2 next (adjacent) to the third boundary BDRY3 between the first light-emitting pixel driver EPD1 and the fourth light-emitting pixel driver EPD4 and extending in the first direction DR1.

The second sharing line CMML2 may be electrically connected to the first light-emitting pixel driver EPD1 and the fourth light-emitting pixel driver EPD4, as well as the second light-emitting pixel driver EPD2 and the fifth light-emitting pixel driver EPD5 that are parallel to the first light-emitting pixel driver EPD1 and the fourth light-emitting pixel driver EPD4 in the first direction DR1.

As illustrated in FIG. 18, in embodiments, the first semiconductor layer SEL1 may include a channel portion CH5, a first electrode E15, and a second electrode E25 of the fifth transistor T5, and a channel portion CH6, a first electrode E16, and a second electrode E26 of the sixth transistor T6.

The first gate conductive layer GCDL1 may include a first capacitor electrode CAE1, a third capacitor electrode CAE3, a first emission control line ECL1, and a second emission control line ECL2.

The second gate conductive layer GCDL2 may include a second capacitor electrode CAE2 and a first reference voltage connection electrode VRCE1.

The first emission control line ECL1 may extend in the first direction DR1 and intersect the channel portion CH5 of the fifth transistor T5.

The first emission control line ECL1 may be disposed per pixel row.

That is, one first emission control line ECL1 may overlap the first light-emitting pixel driver EPD1 and the second light-emitting pixel driver EPD2, and be electrically connected to the fifth transistor T5 of each of the first light-emitting pixel driver EPD1 and the second light-emitting pixel driver EPD2.

Another first emission control line ECL1 may overlap the fourth light-emitting pixel driver EPD4 and the fifth light-emitting pixel driver EPD5, and be electrically connected to the fifth transistor T5 of each of the fourth light-emitting pixel driver EPD4 and the fifth light-emitting pixel driver EPD5.

In an embodiment of FIG. 18, the second emission control line ECL2 may include an emission control main line ECMNL extending in the first direction DR1 and overlapping the first light-emitting pixel driver EPD1 and the second light-emitting pixel driver EPD2, an emission control protruding line ECPRL protruding from the emission control main line ECMNL and extending in the second direction DR2, and an emission control extension line ECEXL connected to the emission control protruding line ECPRL, extending in the first direction DR1, and overlapping the fourth light-emitting pixel driver EPD4 and the fifth light-emitting pixel driver EPD5.

In each of the first light-emitting pixel driver EPD1 and the second light-emitting pixel driver EPD2, the gate electrode G6 of the sixth transistor T6 may be provided as a portion of the emission control main line ECMNL.

In addition, in each of the fourth light-emitting pixel driver EPD4 and the fifth light-emitting pixel driver EPD5, the gate electrode G6 of the sixth transistor T6 may be provided as a portion of the emission control extension line ECEXL.

That is, the second emission control line ECL2 may be electrically connected to the sixth transistors T6 disposed in the first light-emitting pixel driver EPD1, the second light-emitting pixel driver EPD2, the fourth light-emitting pixel driver EPD4, and the fifth light-emitting pixel driver EPD5. The sixth transistor T6 may be turned on by the second emission control signal (EC2 in FIG. 5) of the second emission control line ECL2.

Accordingly, at least one second sharing line CMML2 electrically connected to the first light-emitting pixel driver EPD1, the second light-emitting pixel driver EPD2, the fourth light-emitting pixel driver EPD4, and the fifth light-emitting pixel driver EPD5 may include the second emission control line ECL2.

Therefore, since the number of second emission control lines ECL2 may be reduced to half the number of pixel rows, it may be advantageous in increasing the resolution of the display device 100.

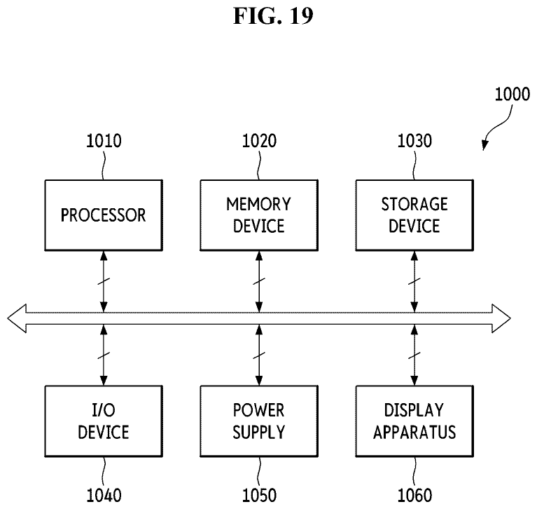

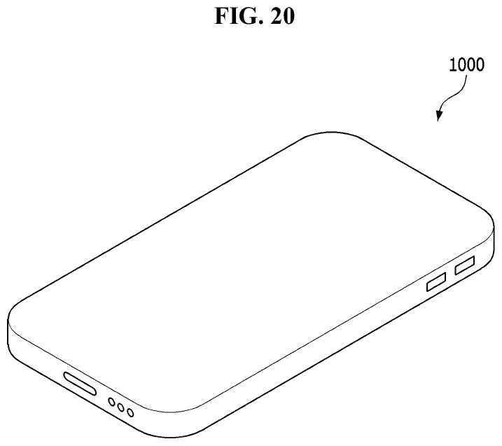

FIG. 19 is a block diagram illustrating an embodiment of an electronic device. FIG. 20 is a view illustrating an embodiment of the electronic device of FIG. 19 implemented as a smartphone.

Referring to FIGS. 19 and 20, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device 100 of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet PC, a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a tablet PC, a vehicle display, a computer monitor, a notebook computer, a head-mounted display device, etc. In addition, the electronic device 1000 may be a television, a monitor, a notebook computer, or a tablet. In addition, the electronic device 1000 may be a car.

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a substrate including a display area in which light-emitting areas are arranged, and a non-display area disposed around the display area;
a circuit layer disposed on the substrate, the circuit layer including:
light-emitting pixel drivers arranged in a first direction and a second direction;
a first sharing line extending in the second direction, next to a first boundary between a first light-emitting pixel driver and a second light-emitting pixel driver next to each other in the first direction among the light-emitting pixel drivers, and electrically connected to the first light-emitting pixel driver and the second light-emitting pixel driver;
a first semiconductor layer disposed on the substrate;
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first inter-insulating layer covering the second gate conductive layer; and
a second semiconductor layer disposed on the first inter-insulating layer; and
an element layer disposed on the circuit layer and including light-emitting elements each disposed in the light-emitting areas and electrically connected to the light-emitting pixel drivers,
wherein one of the light-emitting pixel drivers includes a first transistor which generates a driving current for one of the light-emitting elements,
a channel portion, a first electrode, and a second electrode of the first transistor are disposed in the second semiconductor layer, and
a first semiconductor layer and a second semiconductor layer of the first light-emitting pixel driver are symmetrical with a first semiconductor layer and a second semiconductor layer of the second light-emitting pixel driver with respect to the first boundary.

2. The display device of claim 1, wherein the light-emitting pixel drivers further include:
a third light-emitting pixel driver next to the second light-emitting pixel driver in the first direction;
a fourth light-emitting pixel driver next to the first light-emitting pixel driver in the second direction;
a fifth light-emitting pixel driver next to the second light-emitting pixel driver in the second direction; and
a sixth light-emitting pixel driver next to the third light-emitting pixel driver in the second direction,
the first semiconductor layer and the second semiconductor layer of the second light-emitting pixel driver are symmetrical with a first semiconductor layer and a second semiconductor layer of the third light-emitting pixel driver with respect to a second boundary between the second light-emitting pixel driver and the third light-emitting pixel driver,
the first semiconductor layer and the second semiconductor layer of the first light-emitting pixel driver are symmetrical with a first semiconductor layer and a second semiconductor layer of the fourth light-emitting pixel driver with respect to a third boundary between the first light-emitting pixel driver and the fourth light-emitting pixel driver,
the first semiconductor layer and the second semiconductor layer of the second light-emitting pixel driver are symmetrical with a first semiconductor layer and a second semiconductor layer of the fifth light-emitting pixel driver with respect to an extension line of the third boundary, and
the first sharing line is further electrically connected to the fourth light-emitting pixel driver and the fifth light-emitting pixel driver.

3. The display device of claim 2, wherein the circuit layer further includes:
a data line transmitting a data signal to the light-emitting pixel drivers;
a reference voltage line transmitting a reference voltage to the light-emitting pixel drivers;
an initialization voltage line transmitting an initialization voltage to the light-emitting pixel drivers;
a first power line transmitting a first power to the light-emitting pixel drivers;
a scan write line transmitting a scan write signal to the light-emitting pixel drivers;
a reset control line transmitting a reset control signal to the light-emitting pixel drivers;
a bias control line transmitting a bias control signal to the light-emitting pixel drivers;
a first emission control line transmitting a first emission control signal to the light-emitting pixel drivers; and
a second emission control line transmitting a second emission control signal to the light-emitting pixel drivers.

4. The display device of claim 3, wherein the circuit layer further includes:
a third gate insulating layer covering the second semiconductor layer;
a third gate conductive layer disposed on the third gate insulating layer;
a second inter-insulating layer covering the third gate conductive layer;
a first source drain conductive layer disposed on the second inter-insulating layer;
a first planarization layer covering the first source drain conductive layer;
a second source drain conductive layer disposed on the first planarization layer; and
a second planarization layer covering the second source drain conductive layer, and
the one of the light-emitting pixel drivers includes:
a second transistor electrically connected between a gate electrode of the first transistor and the data line;
a third transistor electrically connected between the gate electrode of the first transistor and the reference voltage line;
a fourth transistor electrically connected between one of the light-emitting elements and the initialization voltage line;
a fifth transistor electrically connected between the first electrode of the first transistor and the first power line;
a sixth transistor electrically connected between the second electrode of the first transistor and the one of the light-emitting elements;
a first capacitor electrically connected between the gate electrode of the first transistor and the second electrode of the first transistor; and
a second capacitor electrically connected between the first power line and the second electrode of the first transistor.

5. The display device of claim 4, wherein the first power line includes:
a first power main line disposed on the third gate conductive layer and extending in the first direction; and
a first power sub-line disposed on the second source drain conductive layer and extending in the second direction, and
the first sharing line includes the first power sub-line.

6. The display device of claim 5, wherein the circuit layer further includes:
an electrode extending portion extending from a first electrode of the sixth transistor;
a first capacitor electrode disposed on the first gate conductive layer, overlapping a portion of the electrode extending portion, and electrically connected to the gate electrode of the first transistor;
a second capacitor electrode disposed on the second gate conductive layer, overlapping the first capacitor electrode, and electrically connected to the second electrode of the first transistor;
a third capacitor electrode disposed on the first gate conductive layer, spaced apart from the first capacitor electrode, overlapping another portion of the electrode extending portion and the second capacitor electrode, and electrically connected to the first power line;
a first power connection auxiliary electrode disposed on the first source drain conductive layer and electrically connected to the third capacitor electrode and the first power main line; and
a second power connection auxiliary electrode disposed on the first source drain conductive layer and electrically connected to a first electrode of the fifth transistor and the first power main line,
a third capacitor electrode of the first light-emitting pixel driver and a third capacitor electrode of the second light-emitting pixel driver are connected to each other at the first boundary,
a second power connection auxiliary electrode of the first light-emitting pixel driver and a second power connection auxiliary electrode of the second light-emitting pixel driver are connected to each other at the first boundary,
the first capacitor is provided as an overlapping area between each of the electrode extending portion and the second capacitor electrode and the first capacitor electrode, and
the second capacitor is provided as an overlapping area between each of the electrode extending portion and the second capacitor electrode and the third capacitor electrode.

7. The display device of claim 6, wherein a first power connection auxiliary electrode of the second light-emitting pixel driver and a first power connection auxiliary electrode of the third light-emitting pixel driver are connected to each other at the second boundary, and are electrically connected to the first electrode of the fifth transistor of the first semiconductor layer.

8. The display device of claim 4, wherein the circuit layer further includes at least one second sharing line extending in the first direction, next to the third boundary, and electrically connected to the first light-emitting pixel driver, the second light-emitting pixel driver, the fourth light-emitting pixel driver, and the fifth light-emitting pixel driver.

9. The display device of claim 8, wherein the fourth transistor is turned on by the bias control signal of the bias control line,
the bias control line is disposed on the third gate conductive layer, extends in the first direction, and overlaps the third boundary, and
the at least one second sharing line includes the bias control line.

10. The display device of claim 8, wherein the initialization voltage line is disposed on the first source drain conductive layer, extends in the first direction, and overlaps the third boundary, and
the at least one second sharing line includes the initialization voltage line.

11. The display device of claim 8, wherein the fifth transistor is turned on by the first emission control signal of the first emission control line,
the sixth transistor is turned on by the second emission control signal of the second emission control line,
the second emission control line includes:
an emission control main line disposed on the first gate conductive layer, extending in the first direction, and overlapping the fourth light-emitting pixel driver and the fifth light-emitting pixel driver;
an emission control protruding line protruding from the emission control main line and extending in the second direction; and
a reset control extension line connected to the emission control protruding line, extending in the first direction, and overlapping the fifth light-emitting pixel driver and the sixth light-emitting pixel driver, and
the at least one second sharing line includes the second emission control line.

12. The display device of claim 4, wherein the light-emitting pixel drivers further include:
a seventh light-emitting pixel driver next to the fourth light-emitting pixel driver in the second direction; and
an eighth light-emitting pixel driver next to the fifth light-emitting pixel driver in the second direction,
a first semiconductor layer and a second semiconductor layer of the seventh light-emitting pixel driver are symmetrical with a first semiconductor layer and a second semiconductor layer of the eighth light-emitting pixel driver with respect to an extension line of the first boundary,
the first semiconductor layer and the second semiconductor layer of the seventh light-emitting pixel driver are symmetrical with a first semiconductor layer and a second semiconductor layer of the fourth light-emitting pixel driver with respect to a fourth boundary between the fourth light-emitting pixel driver and the seventh light-emitting pixel driver,
the first semiconductor layer and the second semiconductor layer of the eighth light-emitting pixel driver are symmetrical with a first semiconductor layer and a second semiconductor layer of the fifth light-emitting pixel driver with respect to an extension line of the fourth boundary, and
the circuit layer further includes:
at least one third sharing line extending in the first direction, next to the fourth boundary, and electrically connected to the fourth light-emitting pixel driver, the fifth light-emitting pixel driver, the seventh light-emitting pixel driver, and the eighth light-emitting pixel driver.

13. The display device of claim 12, wherein the third transistor is turned on by the reset control signal of the reset control line,
the reset control line includes:
a reset control main line disposed on the third gate conductive layer, extending in the first direction, and overlapping the fourth light-emitting pixel driver and the fifth light-emitting pixel driver;
a reset control protruding line protruding from the reset control main line and extending in the second direction; and
a reset control extension line connected to the reset control protruding line, extending in the first direction, and overlapping the seventh light-emitting pixel driver and the eighth light-emitting pixel driver, and
the at least one third sharing line includes the reset control line.

14. The display device of claim 12, wherein the reference voltage line includes:
a reference voltage main line disposed on the second gate conductive layer, extending in the first direction, and overlapping the fourth boundary; and
a reference voltage sub-line disposed on the second source drain conductive layer, extending in the second direction, next to the second boundary, and electrically connected to the reference voltage main line, and
the at least one third sharing line includes the reference voltage main line.

15. An electronic device comprising:
a display device as a display screen,
wherein the display device comprises:
a substrate including a display area in which light-emitting areas are arranged, and a non-display area disposed around the display area;
a circuit layer disposed on the substrate, the circuit layer including:
light-emitting pixel drivers arranged in a first direction and a second direction;
data lines extending in the second direction and transmitting a data signal to the light-emitting pixel drivers;
a first bypass auxiliary line extending in the first direction and electrically connected to a first data line of the data lines next to the non-display area in the first direction;
a second bypass auxiliary line extending in the second direction, next to a second data line of the data lines spaced farther from the non-display area than the first data line in the first direction, and electrically connected to the first bypass auxiliary line; and
a first sharing line extending in the second direction, next to a boundary between two light-emitting pixel drivers next to each other in the first direction among the light-emitting pixel drivers, and electrically connected to the two light-emitting pixel drivers; and
an element layer disposed on the circuit layer and including light-emitting elements each disposed in the light-emitting areas and electrically connected to the light-emitting pixel drivers,
wherein the circuit layer includes a first semiconductor layer disposed on the substrate, and a second semiconductor layer disposed on one or more insulating layers covering the first semiconductor layer,
the two light-emitting pixel drivers include the first semiconductor layer and the second semiconductor layer which are mutually symmetrical with respect to the boundary between the two light-emitting pixel drivers, and
other two light-emitting pixel drivers next to each other in the second direction among the light-emitting pixel drivers include the first semiconductor layer and the second semiconductor layer which are mutually symmetrical with respect to a boundary between the other two light-emitting pixel drivers.

16. The electronic device of claim 15, wherein the circuit layer includes:
the first semiconductor layer;
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first inter-insulating layer covering the second gate conductive layer;
the second semiconductor layer disposed on the first inter-insulating layer;
a third gate insulating layer covering the second semiconductor layer;
a third gate conductive layer disposed on the third gate insulating layer;
a second inter-insulating layer covering the third gate conductive layer;
a first source drain conductive layer disposed on the second inter-insulating layer;
a first planarization layer covering the first source drain conductive layer;
a second source drain conductive layer disposed on the first planarization layer; and
a second planarization layer covering the second source drain conductive layer,
each of the light-emitting pixel drivers includes:
a first transistor;
a second transistor electrically connected between a data line transmitting the data signal and a gate electrode of the first transistor;
a third transistor electrically connected between a reference voltage line transmitting a reference voltage and the gate electrode of the first transistor;
a fourth transistor electrically connected between an initialization voltage line transmitting an initialization voltage and the light-emitting elements;
a fifth transistor electrically connected between a first power line transmitting a first power and a first electrode of the first transistor;
a sixth transistor electrically connected between a second electrode of the first transistor and the light-emitting elements;
a first capacitor electrically connected between the gate electrode of the first transistor and the second electrode of the first transistor; and
a second capacitor electrically connected between the first power line and the second electrode of the first transistor,
a channel portion, a first electrode, and a second electrode of each of the first transistor, the second transistor, the third transistor, and the fourth transistor are disposed on the second semiconductor layer,
a channel portion, a first electrode, and a second electrode of each of the fifth transistor and the sixth transistor are disposed on the first semiconductor layer,
the third transistor is turned on by a reset control signal of a reset control line,
the fourth transistor is turned on by a bias control signal of a bias control line,
the fifth transistor is turned on by a first emission control signal of a first emission control line, and
the sixth transistor is turned on by a second emission control signal of a second emission control line.

17. The electronic device of claim 16, wherein the light-emitting pixel drivers include:
a first light-emitting pixel driver;
a second light-emitting pixel driver next to the first light-emitting pixel driver in the first direction;
a third light-emitting pixel driver next to the second light-emitting pixel driver in the first direction;
a fourth light-emitting pixel driver next to the first light-emitting pixel driver in the second direction;
a fifth light-emitting pixel driver next to the second light-emitting pixel driver in the second direction;
a sixth light-emitting pixel driver next to the third light-emitting pixel driver in the second direction;
a seventh light-emitting pixel driver next to the fourth light-emitting pixel driver in the second direction; and
an eighth light-emitting pixel driver next to the fifth light-emitting pixel driver in the second direction,
the first power line includes:
a first power main line disposed on the third gate conductive layer and extending in the first direction; and
a first power sub-line disposed on the second source drain conductive layer and extending in the second direction, and
the first sharing line is next to a boundary between the first light-emitting pixel driver and the second light-emitting pixel driver, and includes the first power sub-line.

18. The electronic device of claim 17, wherein each of the light-emitting pixel drivers further includes:
an electrode extending portion extending from a first electrode of the sixth transistor;
a first capacitor electrode disposed on the first gate conductive layer, overlapping a portion of the electrode extending portion, and electrically connected to the gate electrode of the first transistor;
a second capacitor electrode disposed on the second gate conductive layer, overlapping the first capacitor electrode, and electrically connected to the second electrode of the first transistor; and
a third capacitor electrode disposed on the first gate conductive layer, spaced apart from the first capacitor electrode, overlapping another portion of the electrode extending portion and the second capacitor electrode, and electrically connected to the first power line,
the first capacitor is provided as an overlapping area between each of the electrode extending portion and the second capacitor electrode and the first capacitor electrode, and
the second capacitor is provided as an overlapping area between each of the electrode extending portion and the second capacitor electrode and the third capacitor electrode.

19. The electronic device of claim 17, wherein the circuit layer further includes:
at least one second sharing line extending in the first direction, next to a boundary between the second light-emitting pixel driver and the third light-emitting pixel driver, and electrically connected to the second light-emitting pixel driver, the third light-emitting pixel driver, the fifth light-emitting pixel driver, and the sixth light-emitting pixel driver,
the second emission control line includes:
an emission control main line disposed on the first gate conductive layer, extending in the first direction, and overlapping the fourth light-emitting pixel driver and the fifth light-emitting pixel driver;
an emission control protruding line protruding from the emission control main line and extending in the second direction; and
a reset control extension line connected to the emission control protruding line, extending in the first direction, and overlapping the fifth light-emitting pixel driver and the sixth light-emitting pixel driver, and
the at least one second sharing line includes at least one of the bias control line, the initialization voltage line, and the second emission control line.

20. The electronic device of claim 17, wherein the circuit layer further includes:
at least one third sharing line extending in the first direction, next to a boundary between the fourth light-emitting pixel driver and the seventh light-emitting pixel driver, and electrically connected to the fourth light-emitting pixel driver, the fifth light-emitting pixel driver, the seventh light-emitting pixel driver, and the eighth light-emitting pixel driver,
the reference voltage line includes:
a reference voltage main line disposed on the second gate conductive layer and extending in the first direction; and
a reference voltage sub-line disposed on the second source drain conductive layer, extending in the second direction, and electrically connected to the reference voltage main line,
the reset control line includes:
a reset control main line extending in the first direction and overlapping the fourth light-emitting pixel driver and the fifth light-emitting pixel driver;
a reset control protruding line protruding from the reset control main line and extending in the second direction; and
a reset control extension line connected to the reset control protruding line, extending in the first direction, and overlapping the seventh light-emitting pixel driver and the eighth light-emitting pixel driver, and
the at least one third sharing line includes at least one of the reference voltage main line and the reset control line.
